(19) United States
(12) Patent Application Publication
(10) Pub. No.: US 2025/0220247 A1
(43) Pub. Date: Jul. 3, 2025

(54) PIXEL PRECONDITIONING FOR NON-NATIVE COMPRESSION

(71) Applicant: QUALCOMM Incorporated, San Diego, CA (US)

(72) Inventors: Sameera Balakrishna MARKOD, Bangalore (IN); Shirin Jahan KODITHODI, Mahadevapura (IN); Venu PAKALAPATY, Bangalore (IN); Prashant Dinkar KARANDIKAR, Bangalore (IN); Swapnil Dattatray RAYKAR, Bangalore (IN)

(21) Appl. No.: 18/398,032

(22) Filed: Dec. 27, 2023

(51) Int. Cl. H04N 19/85; H04N 19/182; H04N 19/184

(52) U.S. Cl. CPC H04N 19/85; H04N 19/182; H04N 19/184

(57) ABSTRACT

This disclosure provides systems, devices, apparatus, and methods, including computer programs encoded on storage media, for pixel preconditioning for non-native compression. A processor obtains a set of bits including a first subset of bits and a second subset of bits, where a bit width of the set of bits is greater than a configured bit width of compression hardware. The processor processes the first subset of bits based on a parity corresponding to the second subset of bits. The processor outputs, for a decoder of the compression hardware, the set of bits including the processed first subset of bits and the second subset of bits.

### TECHNICAL FIELD

The present disclosure relates generally to processing systems, and more particularly, to one or more techniques for data processing.

### INTRODUCTION

Computing devices often perform graphics and/or display processing (e.g., utilizing a graphics processing unit (GPU), a central processing unit (CPU), a display processor, etc.) to render and display visual content. Such computing devices may include, for example, computer workstations, mobile phones such as smartphones, embedded systems, personal computers, tablet computers, and video game consoles. GPUs are configured to execute a graphics processing pipeline that includes one or more processing stages, which operate together to execute graphics processing commands and output a frame. A central processing unit (CPU) may control the operation of the GPU by issuing one or more graphics processing commands to the GPU. Modern day CPUs are typically capable of executing multiple applications concurrently, each of which may need to utilize the GPU during execution. A display processor may be configured to convert digital information received from a CPU to analog values and may issue commands to a display panel for displaying the visual content. A device that provides content for visual presentation on a display may utilize a CPU, a GPU, and/or a display processor.

Current techniques for non-native compression may be associated with a relatively high amount of prediction error. There is a need for improved techniques pertaining to non-native compression.

### BRIEF SUMMARY

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description that is presented later.

In an aspect of the disclosure, a method, a computer-readable medium, and an apparatus for data processing are provided. The apparatus includes a memory; and a processor coupled to the memory and, based on information stored in the memory, the processor is configured to: obtain a set of bits including a first subset of bits and a second subset of bits, where a bit width of the set of bits is greater than a configured bit width of compression hardware; process the first subset of bits based on a parity corresponding to the second subset of bits; and output, for a decoder of the compression hardware, the set of bits including the processed first subset of bits and the second subset of bits.

In an aspect of the disclosure, a method, a computer-readable medium, and an apparatus for data processing are provided. The apparatus includes a memory; and a processor coupled to the memory and, based on information stored in the memory, the processor is configured to: obtain, from an encoder of compression hardware, a set of bits including a first subset of bits and a second subset of bits, where a bit width of the set of bits is greater than a configured bit width of the compression hardware; process the first subset of bits based on a parity corresponding to the second subset of bits; and output the set of bits including the processed first subset of bits and the second subset of bits.

To the accomplishment of the foregoing and related ends, the one or more aspects include the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

FIG. 1 is a block diagram that illustrates an example content generation system in accordance with one or more techniques of this disclosure.

FIG. 2 illustrates an example GPU in accordance with one or more techniques of this disclosure.

FIG. 3 illustrates an example image or surface in accordance with one or more techniques of this disclosure.

FIG. 4 is a diagram illustrating an example of native compression in accordance with one or more techniques of this disclosure.

FIG. 5 is a diagram illustrating an example of non-native compression in accordance with one or more techniques of this disclosure.

FIG. 6 is a diagram illustrating an example of native decompression in accordance with one or more techniques of this disclosure.

FIG. 7 is a diagram illustrating an example of non-native decompression in accordance with one or more techniques of this disclosure.

FIG. 8 is a diagram illustrating a first plot of a most significant bit (MSB) versus a native bit component value and a second plot of a least significant bit (LSB) versus a native bit component value in accordance with one or more techniques of this disclosure.

FIG. 9 is a diagram illustrating example aspects pertaining to pixel preconditioning in accordance with one or more techniques of this disclosure.

FIG. 10 is a diagram illustrating example aspects pertaining to encoding in accordance with one or more techniques of this disclosure.

FIG. 11 is a diagram illustrating example aspects pertaining to decoding in accordance with one or more techniques of this disclosure.

FIG. 12 is a call flow diagram illustrating example communications between an encoder and a decoder in accordance with one or more techniques of this disclosure.

FIG. 13 is a flowchart of an example method of graphics processing in accordance with one or more techniques of this disclosure.

FIG. 14 is a flowchart of an example method of graphics processing in accordance with one or more techniques of this disclosure.

FIG. 15 is a flowchart of an example method of graphics processing in accordance with one or more techniques of this disclosure.

FIG. 16 is a flowchart of an example method of graphics processing in accordance with one or more techniques of this disclosure.

### DETAILED DESCRIPTION

Various aspects of systems, apparatuses, computer program products, and methods are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of this disclosure to those skilled in the art. Based on the teachings herein one skilled in the art should appreciate that the scope of this disclosure is intended to cover any aspect of the systems, apparatuses, computer program products, and methods disclosed herein, whether implemented independently of, or combined with, other aspects of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. Any aspect disclosed herein may be embodied by one or more elements of a claim.

Although various aspects are described herein, many variations and permutations of these aspects fall within the scope of this disclosure. Although some potential benefits and advantages of aspects of this disclosure are mentioned, the scope of this disclosure is not intended to be limited to particular benefits, uses, or objectives. Rather, aspects of this disclosure are intended to be broadly applicable to different wireless technologies, system configurations, processing systems, networks, and transmission protocols, some of which are illustrated by way of example in the figures and in the following description. The detailed description and drawings are merely illustrative of this disclosure rather than limiting, the scope of this disclosure being defined by the appended claims and equivalents thereof.

Several aspects are presented with reference to various apparatus and methods. These apparatus and methods are described in the following detailed description and illustrated in the accompanying drawings by various blocks, components, circuits, processes, algorithms, and the like (collectively referred to as “elements”). These elements may be implemented using electronic hardware, computer software, or any combination thereof. Whether such elements are implemented as hardware or software depends upon the particular application and design constraints imposed on the overall system.

By way of example, an element, or any portion of an element, or any combination of elements may be implemented as a “processing system” that includes one or more processors (which may also be referred to as processing units). Examples of processors include microprocessors, microcontrollers, graphics processing units (GPUs), general purpose GPUs (GPGPUs), central processing units (CPUs), application processors, digital signal processors (DSPs), reduced instruction set computing (RISC) processors, systems-on-chip (SOCs), baseband processors, application specific integrated circuits (ASICs), field programmable gate arrays (FPGAs), programmable logic devices (PLDs), state machines, gated logic, discrete hardware circuits, and other suitable hardware configured to perform the various functionality described throughout this disclosure. One or more processors in the processing system may execute software. Software can be construed broadly to mean instructions, instruction sets, code, code segments, program code, programs, subprograms, software components, applications, software applications, software packages, routines, subroutines, objects, executables, threads of execution, procedures, functions, etc., whether referred to as software, firmware, middleware, microcode, hardware description language, or otherwise.

The term application may refer to software. As described herein, one or more techniques may refer to an application (e.g., software) being configured to perform one or more functions. In such examples, the application may be stored in a memory (e.g., on-chip memory of a processor, system memory, or any other memory). Hardware described herein, such as a processor may be configured to execute the application. For example, the application may be described as including code that, when executed by the hardware, causes the hardware to perform one or more techniques described herein. As an example, the hardware may access the code from a memory and execute the code accessed from the memory to perform one or more techniques described herein. In some examples, components are identified in this disclosure. In such examples, the components may be hardware, software, or a combination thereof. The components may be separate components or sub-components of a single component. As used herein the term “bit component” may refer to a set of bits.

In one or more examples described herein, the functions described may be implemented in hardware, software, or any combination thereof. If implemented in software, the functions may be stored on or encoded as one or more instructions or code on a computer-readable medium. Computer-readable media includes computer storage media. Storage media may be any available media that can be accessed by a computer. By way of example, and not limitation, such computer-readable media can include a random access memory (RAM), a read-only memory (ROM), an electrically erasable programmable ROM (EEPROM), optical disk storage, magnetic disk storage, other magnetic storage devices, combinations of the aforementioned types of computer-readable media, or any other medium that can be used to store computer executable code in the form of instructions or data structures that can be accessed by a computer.

As used herein, instances of the term “content” may refer to “graphical content,” an “image,” etc., regardless of whether the terms are used as an adjective, noun, or other parts of speech. In some examples, the term “graphical content,” as used herein, may refer to a content produced by one or more processes of a graphics processing pipeline. In further examples, the term “graphical content,” as used herein, may refer to a content produced by a processing unit configured to perform graphics processing. In still further examples, as used herein, the term “graphical content” may refer to a content produced by a graphics processing unit.

Data compression may refer to a process of encoding, restructuring, and/or otherwise modifying data in order to reduce a size of the data. Data decompression may refer to a process of reconstructing the data compressed by a data compression process. Data compression/decompression may be used for various purposes, such as reducing a size of data transmitted between a first device and a second device or reducing a size of data transmitted between a first component and a second component of a device, which may reduce bandwidth demands and hence may be associated with increased performance. Data compression/decompression may be based on a compression/decompression format, where the compression/decompression format may be associated with a first bit width. In an example, a compression/decompression format may be associated with processing groups of ten bits of data at a time, that is, the compression/decompression format may have a bit width of ten bits. In another example, a compression/decompression format may be associated with processing groups of twelve bits of data at a time, that is, the compression/decompression format may have a bit width of twelve bits.

A device (or a component of the device) may include compression hardware and/or decompression hardware, where the compression hardware may be configured to compress data and where the decompression hardware may be configured to decompress the data. The compression/decompression hardware may be configured with a second bit width. The second bit width of the compression/decompression hardware may be the same as the first bit width of the compression/decompression format or the second bit width of the compression/decompression hardware may be different from the first bit width of the compression/decompression format. When compression/decompression hardware compresses/decompresses data using a compression/decompression format that has the same bit width as a bit width of the compression/decompression hardware, the compression/decompression of the data may be referred to as “native compression/decompression.” When compression/decompression hardware compresses/decompresses data using a compression/decompression format that has a different bit width as a bit width of the compression/decompression hardware, the compression/decompression of the data may be referred to as “non-native compression/decompression.”

In an example with respect to non-native compression, a bit width of the compression/decompression format may be greater than a bit width of the compression/decompression hardware. In the example, a set of bits (i.e., data) may be split into a first subset of bits and a second subset of bits, and the first subset of bits and the second subset of bits may be processed independently by the compression/decompression hardware. For instance, a first compression unit of the compression/decompression hardware may compress the first subset of bits and a second compression unit of the compression/decompression hardware may compress the second subset of bits. However, splitting the set of bits and compressing the set of bits in the aforementioned manner may cause a relatively large prediction error for the set of bits, which may lead to a reduction in a compression ratio. The reduction in the compression ratio may result in a relatively higher amount of bandwidth being utilized for a compression/decompression process.

Various technologies pertaining to pixel pre-conditioning for non-native compression are described herein. In an example, an apparatus (e.g., an encoder) obtains a set of bits including a first subset of bits and a second subset of bits, where a bit width of the set of bits is greater than a configured bit width of compression hardware. The apparatus (e.g., an encoder) processes the first subset of bits based on a parity corresponding to the second subset of bits. Parity may refer to whether a number represented by a set or a subset of bits is even or odd. The apparatus (e.g., an encoder) outputs, for a decoder of the compression hardware, the set of bits including the processed first subset of bits and the second subset of bits. Vis-à-vis processing the first subset of bits based on the parity corresponding to the second subset of bits, the apparatus may remove a discontinuity associated with the first subset of bits, which may improve a compression ratio when the set of bits is compressed. The improved compression ratio may be associated with a conservation of computing resources and/or network resources. In another example, an apparatus (e.g., a decoder) obtains, from an encoder of compression hardware, a set of bits including a first subset of bits and a second subset of bits, where a bit width of the set of bits is greater than a configured bit width of the compression hardware. The apparatus (e.g., a decoder) processes the first subset of bits based on a parity corresponding to the second subset of bits. The apparatus (e.g., a decoder) outputs the set of bits including the processed first subset of bits and the second subset of bits. Vis-à-vis processing the first subset of bits based on the parity corresponding to the second subset of bits, the apparatus may remove a discontinuity associated with the first subset of bits, which may conserve computing resources of the apparatus.

The examples describe herein may refer to a use and functionality of a graphics processing unit (GPU). As used herein, a GPU can be any type of graphics processor, and a graphics processor can be any type of processor that is designed or configured to process graphics content. For example, a graphics processor or GPU can be a specialized electronic circuit that is designed for processing graphics content. As an additional example, a graphics processor or GPU can be a general purpose processor that is configured to process graphics content.

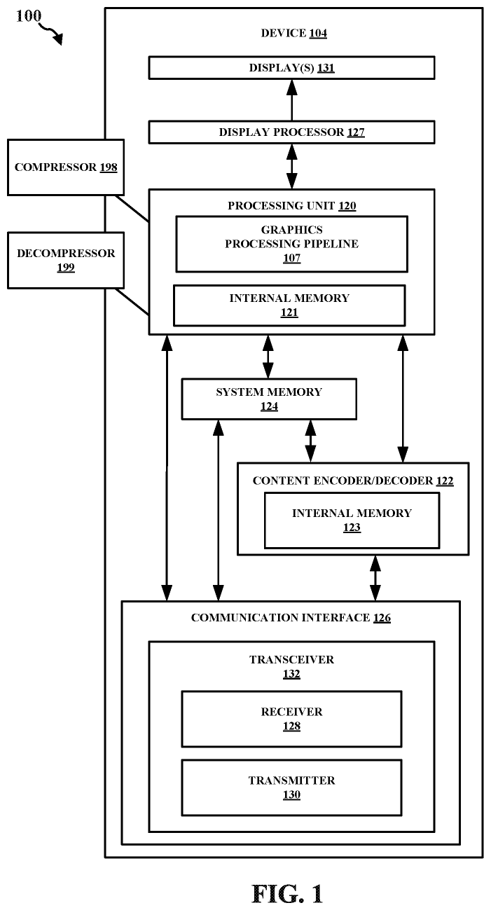

FIG. 1 is a block diagram that illustrates an example content generation system 100 configured to implement one or more techniques of this disclosure. The content generation system 100 includes a device 104. The device 104 may include one or more components or circuits for performing various functions described herein. In some examples, one or more components of the device 104 may be components of a SOC. The device 104 may include one or more components configured to perform one or more techniques of this disclosure. In the example shown, the device 104 may include a processing unit 120, a content encoder/decoder 122, and a system memory 124. In some aspects, the device 104 may include a number of components (e.g., a communication interface 126, a transceiver 132, a receiver 128, a transmitter 130, a display processor 127, and one or more displays 131). Display(s) 131 may refer to one or more displays 131. For example, the display 131 may include a single display or multiple displays, which may include a first display and a second display. The first display may be a left-eye display and the second display may be a right-eye display. In some examples, the first display and the second display may receive different frames for presentment thereon. In other examples, the first and second display may receive the same frames for presentment thereon. In further examples, the results of the graphics processing may not be displayed on the device, e.g., the first display and the second display may not receive any frames for presentment thereon. Instead, the frames or graphics processing results may be transferred to another device. In some aspects, this may be referred to as split-rendering.

The processing unit 120 may include an internal memory 121. The processing unit 120 may be configured to perform graphics processing using a graphics processing pipeline 107. The content encoder/decoder 122 may include an internal memory 123. In some examples, the device 104 may include a processor, which may be configured to perform one or more display processing techniques on one or more frames generated by the processing unit 120 before the frames are displayed by the one or more displays 131. While the processor in the example content generation system 100 is configured as a display processor 127, it should be understood that the display processor 127 is one example of the processor and that other types of processors, controllers, etc., may be used as substitute for the display processor 127. The display processor 127 may be configured to perform display processing. For example, the display processor 127 may be configured to perform one or more display processing techniques on one or more frames generated by the processing unit 120. The one or more displays 131 may be configured to display or otherwise present frames processed by the display processor 127. In some examples, the one or more displays 131 may include one or more of a liquid crystal display (LCD), a plasma display, an organic light emitting diode (OLED) display, a projection display device, an augmented reality display device, a virtual reality display device, a head-mounted display, or any other type of display device.

Memory external to the processing unit 120 and the content encoder/decoder 122, such as system memory 124, may be accessible to the processing unit 120 and the content encoder/decoder 122. For example, the processing unit 120 and the content encoder/decoder 122 may be configured to read from and/or write to external memory, such as the system memory 124. The processing unit 120 may be communicatively coupled to the system memory 124 over a bus. In some examples, the processing unit 120 and the content encoder/decoder 122 may be communicatively coupled to the internal memory 121 over the bus or via a different connection.

The content encoder/decoder 122 may be configured to receive graphical content from any source, such as the system memory 124 and/or the communication interface 126. The system memory 124 may be configured to store received encoded or decoded graphical content. The content encoder/decoder 122 may be configured to receive encoded or decoded graphical content, e.g., from the system memory 124 and/or the communication interface 126, in the form of encoded pixel data. The content encoder/decoder 122 may be configured to encode or decode any graphical content.

The internal memory 121 or the system memory 124 may include one or more volatile or non-volatile memories or storage devices. In some examples, internal memory 121 or the system memory 124 may include RAM, static random access memory (SRAM), dynamic random access memory (DRAM), erasable programmable ROM (EPROM), EEPROM, flash memory, a magnetic data media or an optical storage media, or any other type of memory. The internal memory 121 or the system memory 124 may be a non-transitory storage medium according to some examples. The term “non-transitory” may indicate that the storage medium is not embodied in a carrier wave or a propagated signal. However, the term “non-transitory” should not be interpreted to mean that internal memory 121 or the system memory 124 is non-movable or that its contents are static. As one example, the system memory 124 may be removed from the device 104 and moved to another device. As another example, the system memory 124 may not be removable from the device 104.

The processing unit 120 may be a CPU, a GPU, a GPGPU, or any other processing unit that may be configured to perform graphics processing. In some examples, the processing unit 120 may be integrated into a motherboard of the device 104. In further examples, the processing unit 120 may be present on a graphics card that is installed in a port of the motherboard of the device 104, or may be otherwise incorporated within a peripheral device configured to interoperate with the device 104. The processing unit 120 may include one or more processors, such as one or more microprocessors, GPUs, ASICs, FPGAs, arithmetic logic units (ALUs), DSPs, discrete logic, software, hardware, firmware, other equivalent integrated or discrete logic circuitry, or any combinations thereof. If the techniques are implemented partially in software, the processing unit 120 may store instructions for the software in a suitable, non-transitory computer-readable storage medium, e.g., internal memory 121, and may execute the instructions in hardware using one or more processors to perform the techniques of this disclosure. Any of the foregoing, including hardware, software, a combination of hardware and software, etc., may be considered to be one or more processors.

The content encoder/decoder 122 may be any processing unit configured to perform content decoding. In some examples, the content encoder/decoder 122 may be integrated into a motherboard of the device 104. The content encoder/decoder 122 may include one or more processors, such as one or more microprocessors, application specific integrated circuits (ASICs), field programmable gate arrays (FPGAs), arithmetic logic units (ALUs), digital signal processors (DSPs), video processors, discrete logic, software, hardware, firmware, other equivalent integrated or discrete logic circuitry, or any combinations thereof. If the techniques are implemented partially in software, the content encoder/decoder 122 may store instructions for the software in a suitable, non-transitory computer-readable storage medium, e.g., internal memory 123, and may execute the instructions in hardware using one or more processors to perform the techniques of this disclosure. Any of the foregoing, including hardware, software, a combination of hardware and software, etc., may be considered to be one or more processors.

In some aspects, the content generation system 100 may include a communication interface 126. The communication interface 126 may include a receiver 128 and a transmitter 130. The receiver 128 may be configured to perform any receiving function described herein with respect to the device 104. Additionally, the receiver 128 may be configured to receive information, e.g., eye or head position information, rendering commands, and/or location information, from another device. The transmitter 130 may be configured to perform any transmitting function described herein with respect to the device 104. For example, the transmitter 130 may be configured to transmit information to another device, which may include a request for content. The receiver 128 and the transmitter 130 may be combined into a transceiver 132. In such examples, the transceiver 132 may be configured to perform any receiving function and/or transmitting function described herein with respect to the device 104.

Referring again to FIG. 1, in certain aspects, the processing unit 120 may include a compressor 198 configured to obtain a set of bits including a first subset of bits and a second subset of bits, where a bit width of the set of bits is greater than a configured bit width of compression hardware; process the first subset of bits based on a parity corresponding to the second subset of bits; and output, for a decoder of the compression hardware, the set of bits including the processed first subset of bits and the second subset of bits. In certain aspects, the processing unit 120 may include a decompressor 199 configured to obtain, from an encoder of compression hardware, a set of bits including a first subset of bits and a second subset of bits, where a bit width of the set of bits is greater than a configured bit width of the compression hardware; process the first subset of bits based on a parity corresponding to the second subset of bits; and output the set of bits including the processed first subset of bits and the second subset of bits. Although the following description may be focused on data processing and graphics processing, the concepts described herein may be applicable to other similar processing techniques. For instance, the concepts presented herein may be applicable for compressing and decompressing types of data other than graphics related data such as pixel data. A pixel may refer to a smallest addressable element in an image. A frame may refer to an image in a sequence of images. Furthermore, although the description herein may focus on bit widths of 10 bits, 12 bits, 14 bits, or 16 bits, the concepts described herein may be applicable to other bit widths as well (e.g., 15 bits, 18 bits, etc.).

A device, such as the device 104, may refer to any device, apparatus, or system configured to perform one or more techniques described herein. For example, a device may be a server, a base station, a user equipment, a client device, a station, an access point, a computer such as a personal computer, a desktop computer, a laptop computer, a tablet computer, a computer workstation, or a mainframe computer, an end product, an apparatus, a phone, a smart phone, a server, a video game platform or console, a handheld device such as a portable video game device or a personal digital assistant (PDA), a wearable computing device such as a smart watch, an augmented reality device, or a virtual reality device, a non-wearable device, a display or display device, a television, a television set-top box, an intermediate network device, a digital media player, a video streaming device, a content streaming device, an in-vehicle computer, any mobile device, any device configured to generate graphical content, or any device configured to perform one or more techniques described herein. Processes herein may be described as performed by a particular component (e.g., a GPU) but in other embodiments, may be performed using other components (e.g., a CPU) consistent with the disclosed embodiments.

GPUs can process multiple types of data or data packets in a GPU pipeline. For instance, in some aspects, a GPU can process two types of data or data packets, e.g., context register packets and draw call data. A context register packet can be a set of global state information, e.g., information regarding a global register, shading program, or constant data, which can regulate how a graphics context will be processed. For example, context register packets can include information regarding a color format. In some aspects of context register packets, there can be a bit or bits that indicate which workload belongs to a context register. Also, there can be multiple functions or programming running at the same time and/or in parallel. For example, functions or programming can describe a certain operation, e.g., the color mode or color format. Accordingly, a context register can define multiple states of a GPU.

Context states can be utilized to determine how an individual processing unit functions, e.g., a vertex fetcher (VFD), a vertex shader (VS), a shader processor, or a geometry processor, and/or in what mode the processing unit functions. In order to do so, GPUs can use context registers and programming data. In some aspects, a GPU can generate a workload, e.g., a vertex or pixel workload, in the pipeline based on the context register definition of a mode or state. Certain processing units, e.g., a VFD, can use these states to determine certain functions, e.g., how a vertex is assembled. As these modes or states can change, GPUs may need to change the corresponding context. Additionally, the workload that corresponds to the mode or state may follow the changing mode or state.

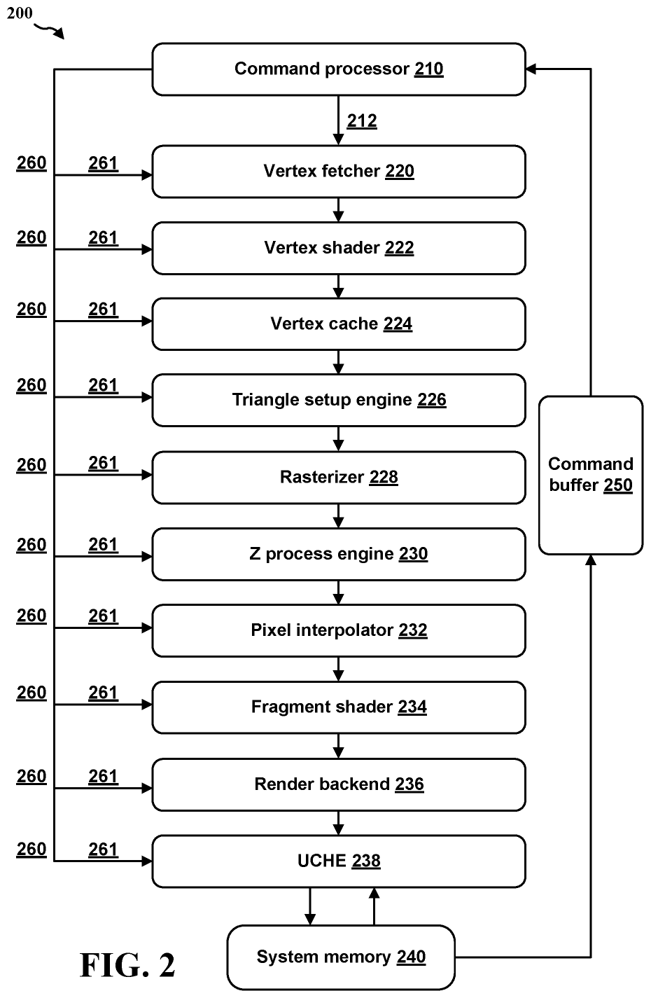

FIG. 2 illustrates an example GPU 200 in accordance with one or more techniques of this disclosure. As shown in FIG. 2, GPU 200 includes command processor (CP) 210, draw call packets 212, VFD 220, VS 222, vertex cache (VPC) 224, triangle setup engine (TSE) 226, rasterizer (RAS) 228, Z process engine (ZPE) 230, pixel interpolator (PI) 232, fragment shader (FS) 234, render backend (RB) 236, L2 cache (UCHE) 238, and system memory 240. Although FIG. 2 displays that GPU 200 includes processing units 220-238, GPU 200 can include a number of additional processing units. Additionally, processing units 220-238 are merely an example and any combination or order of processing units can be used by GPUs according to the present disclosure. GPU 200 also includes command buffer 250, context register packets 260, and context states 261.

As shown in FIG. 2, a GPU can utilize a CP, e.g., CP 210, or hardware accelerator to parse a command buffer into context register packets, e.g., context register packets 260, and/or draw call data packets, e.g., draw call packets 212. The CP 210 can then send the context register packets 260 or draw call packets 212 through separate paths to the processing units or blocks in the GPU. Further, the command buffer 250 can alternate different states of context registers and draw calls. For example, a command buffer can simultaneously store the following information: context register of context N, draw call(s) of context N, context register of context N+1, and draw call(s) of context N+1.

GPUs can render images in a variety of different ways. In some instances, GPUs can render an image using direct rendering and/or tiled rendering. In tiled rendering GPUs, an image can be divided or separated into different sections or tiles. After the division of the image, each section or tile can be rendered separately. Tiled rendering GPUs can divide computer graphics images into a grid format, such that each portion of the grid, i.e., a tile, is separately rendered. In some aspects of tiled rendering, during a binning pass, an image can be divided into different bins or tiles. In some aspects, during the binning pass, a visibility stream can be constructed where visible primitives or draw calls can be identified. A rendering pass may be performed after the binning pass. In contrast to tiled rendering, direct rendering does not divide the frame into smaller bins or tiles. Rather, in direct rendering, the entire frame is rendered at a single time (i.e., without a binning pass). Additionally, some types of GPUs can allow for both tiled rendering and direct rendering (e.g., flex rendering).

In some aspects, GPUs can apply the drawing or rendering process to different bins or tiles. For instance, a GPU can render to one bin, and perform all the draws for the primitives or pixels in the bin. During the process of rendering to a bin, the render targets can be located in GPU internal memory (GMEM). In some instances, after rendering to one bin, the content of the render targets can be moved to a system memory and the GMEM can be freed for rendering the next bin. Additionally, a GPU can render to another bin, and perform the draws for the primitives or pixels in that bin. Therefore, in some aspects, there might be a small number of bins, e.g., four bins, that cover all of the draws in one surface. Further, GPUs can cycle through all of the draws in one bin, but perform the draws for the draw calls that are visible, i.e., draw calls that include visible geometry. In some aspects, a visibility stream can be generated, e.g., in a binning pass, to determine the visibility information of each primitive in an image or scene. For instance, this visibility stream can identify whether a certain primitive is visible or not. In some aspects, this information can be used to remove primitives that are not visible so that the non-visible primitives are not rendered, e.g., in the rendering pass. Also, at least some of the primitives that are identified as visible can be rendered in the rendering pass.

In some aspects of tiled rendering, there can be multiple processing phases or passes. For instance, the rendering can be performed in two passes, e.g., a binning, a visibility or bin-visibility pass and a rendering or bin-rendering pass. During a visibility pass, a GPU can input a rendering workload, record the positions of the primitives or triangles, and then determine which primitives or triangles fall into which bin or area. In some aspects of a visibility pass, GPUs can also identify or mark the visibility of each primitive or triangle in a visibility stream. During a rendering pass, a GPU can input the visibility stream and process one bin or area at a time. In some aspects, the visibility stream can be analyzed to determine which primitives, or vertices of primitives, are visible or not visible. As such, the primitives, or vertices of primitives, that are visible may be processed. By doing so, GPUs can reduce the unnecessary workload of processing or rendering primitives or triangles that are not visible.

In some aspects, during a visibility pass, certain types of primitive geometry, e.g., position-only geometry, may be processed. Additionally, depending on the position or location of the primitives or triangles, the primitives may be sorted into different bins or areas. In some instances, sorting primitives or triangles into different bins may be performed by determining visibility information for these primitives or triangles. For example, GPUs may determine or write visibility information of each primitive in each bin or area, e.g., in a system memory. This visibility information can be used to determine or generate a visibility stream. In a rendering pass, the primitives in each bin can be rendered separately. In these instances, the visibility stream can be fetched from memory and used to remove primitives which are not visible for that bin. Some aspects of GPUs or GPU architectures can provide a number of different options for rendering, e.g., software rendering and hardware rendering. In software rendering, a driver or CPU can replicate an entire frame geometry by processing each view one time. Additionally, some different states may be changed depending on the view. As such, in software rendering, the software can replicate the entire workload by changing some states that may be utilized to render for each viewpoint in an image. In certain aspects, as GPUs may be submitting the same workload multiple times for each viewpoint in an image, there may be an increased amount of overhead. In hardware rendering, the hardware or GPU may be responsible for replicating or processing the geometry for each viewpoint in an image. Accordingly, the hardware can manage the replication or processing of the primitives or triangles for each viewpoint in an image.

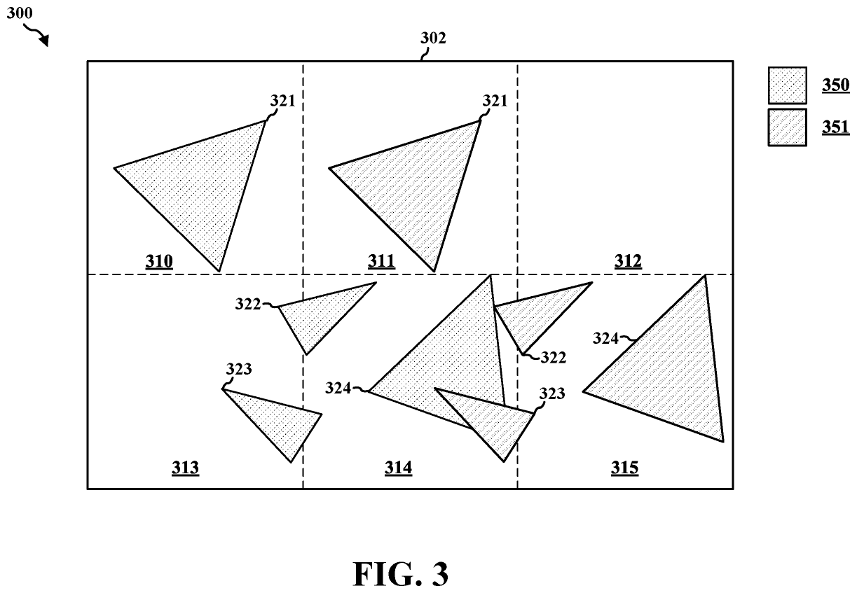

FIG. 3 illustrates image or surface 300, including multiple primitives divided into multiple bins in accordance with one or more techniques of this disclosure. As shown in FIG. 3, image or surface 300 includes area 302, which includes primitives 321, 322, 323, and 324. The primitives 321, 322, 323, and 324 are divided or placed into different bins, e.g., bins 310, 311, 312, 313, 314, and 315. FIG. 3 illustrates an example of tiled rendering using multiple viewpoints for the primitives 321-324. For instance, primitives 321-324 are in first viewpoint 350 and second viewpoint 351. As such, the GPU processing or rendering the image or surface 300 including area 302 can utilize multiple viewpoints or multi-view rendering.

As indicated herein, GPUs or graphics processors can use a tiled rendering architecture to reduce power consumption or save memory bandwidth. As further stated above, this rendering method can divide the scene into multiple bins, as well as include a visibility pass that identifies the triangles that are visible in each bin. Thus, in tiled rendering, a full screen can be divided into multiple bins or tiles. The scene can then be rendered multiple times, e.g., one or more times for each bin.

In aspects of graphics rendering, some graphics applications may render to a single target, i.e., a render target, one or more times. For instance, in graphics rendering, a frame buffer on a system memory may be updated multiple times. The frame buffer can be a portion of memory or random access memory (RAM), e.g., containing a bitmap or storage, to help store display data for a GPU. The frame buffer can also be a memory buffer containing a complete frame of data. Additionally, the frame buffer can be a logic buffer. In some aspects, updating the frame buffer can be performed in bin or tile rendering, where, as discussed above, a surface is divided into multiple bins or tiles and then each bin or tile can be separately rendered. Further, in tiled rendering, the frame buffer can be partitioned into multiple bins or tiles.

As indicated herein, in some aspects, such as in bin or tiled rendering architecture, frame buffers can have data stored or written to them repeatedly, e.g., when rendering from different types of memory. This can be referred to as resolving and unresolving the frame buffer or system memory. For example, when storing or writing to one frame buffer and then switching to another frame buffer, the data or information on the frame buffer can be resolved from the GMEM at the GPU to the system memory, i.e., memory in the double data rate (DDR) RAM or dynamic RAM (DRAM).

In some aspects, the system memory can also be system-on-chip (SoC) memory or another chip-based memory to store data or information, e.g., on a device or smart phone. The system memory can also be physical data storage that is shared by the CPU and/or the GPU. In some aspects, the system memory can be a DRAM chip, e.g., on a device or smart phone. Accordingly, SoC memory can be a chip-based manner in which to store data.

In some aspects, the GMEM can be on-chip memory at the GPU, which can be implemented by static RAM (SRAM). Additionally, GMEM can be stored on a device, e.g., a smart phone. As indicated herein, data or information can be transferred between the system memory or DRAM and the GMEM, e.g., at a device. In some aspects, the system memory or DRAM can be at the CPU or GPU. Additionally, data can be stored at the DDR or DRAM. In some aspects, such as in bin or tiled rendering, a small portion of the memory can be stored at the GPU, e.g., at the GMEM. In some instances, storing data at the GMEM may utilize a larger processing workload and/or consume more power compared to storing data at the frame buffer or system memory.

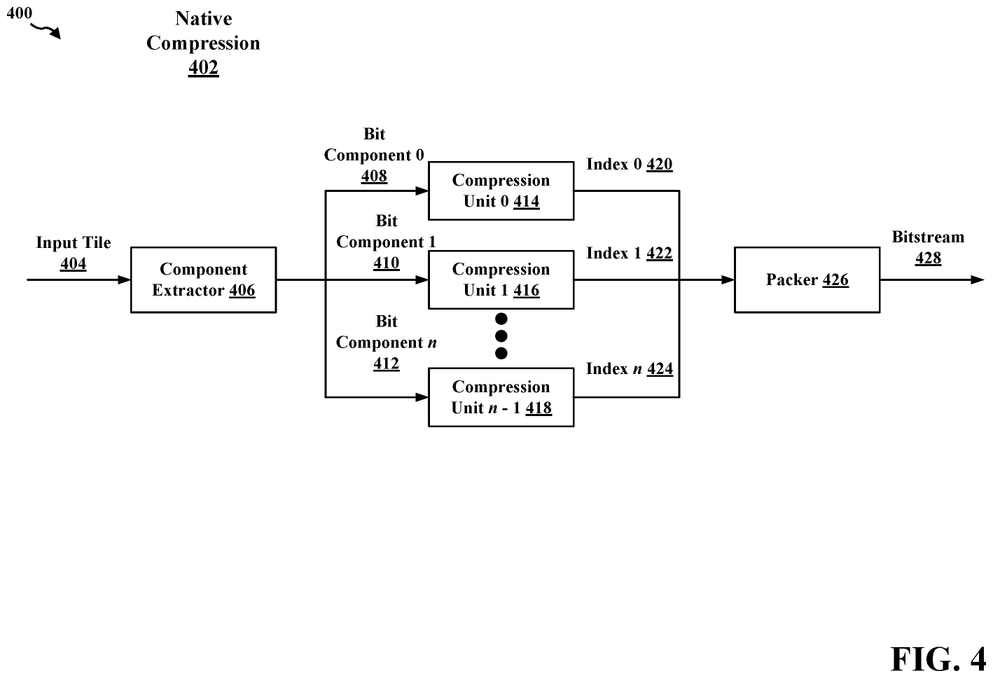

FIG. 4 is a diagram 400 illustrating an example of native compression 402 in accordance with one or more techniques of this disclosure. The native compression 402 may also be referred to as “native encoding.” In an example, the native compression 402 may be performed by the device 104. Universal bandwidth compression (UBWC) may refer to a compression/decompression standard that may be used to compress/decompress graphical buffers (i.e., graphical data), such as graphics processor buffers, video buffers, and/or camera buffers. UBWC may operate on a per-tile basis, where each tile may include a defined number of pixels (e.g., four pixels, eight pixels, etc.). UBWC may be used to compress/decompress graphical buffers transmitted within a device (e.g., from one hardware block of a device to another hardware block of the device). UBWC may also be used to compress/decompress graphical buffers transmitted between devices (e.g., from a first device to a second device). Hardware of a device may be configured to perform compression/decompression via UBWC. For UBWC, as a bit width of a bit component (i.e., a set of bits) increase, complexity of the hardware may increase (e.g., timing, area). A bit may refer to a logical state with one of two possible values (zero or one). A bit width may refer to a number of bits in a set of bits.

UBWC may include different variants. Some example variants of UBWC that operate on 10-bit components may include UBWC_RGBA8888, UBWC_RGBA1010102, UBWC_NV12-Y, UBWC_NV-12-UV, UBWC_TP10-Y, UBWC_TP10-UV, UBWC_NV124R-Y, and UBWC_NV124R-UV. Some example variants of UBWC that operate on more than 10-bit components may include UBWC_P016 (16 bits), UBWC_TBAYER12 (12 bits), and UBWC_TBAYER14 (14 bits).

Compression/decompression hardware may be configured to operate on a first number of bits (i.e., a first bit width) of data, that is, the compression/decompression hardware may be configured to process the data based on the number of bits. For example, if one hundred bits are to be compressed and the first number of bits is ten, a first compression unit of the compression/decompression hardware may compress bits zero through nine of the data, a second compression unit of the compression/decompression hardware may compress bits ten through nineteen of the data, and so forth.

A compression/decompression format (e.g., UBWC) may be associated with processing a second number of bits (i.e., a second bit width) of data. For example, if one hundred bits are to be compressed and the second number of bits of the compression/decompression format is ten, the compression/decompression format may dictate that the one hundred bits be processed (e.g., compressed) in groups of ten.

The first number of bits may be the same as the second number of bits or the first number of bits may be different from the second number of bits. When the first number of bits is equal to the second number of bits, compression may be referred to as “native compression” and decompression may be referred to as “native decompression.” When the first number of bits is not equal to the second number of bits (i.e., the first number of bits is different from the second number of bits), compression may be referred to as “non-native compression” and decompression may be referred to as “non-native decompression.”

In an example in which the second number of bits of the compression/decompression format is greater than the first number of bits of the compression/decompression hardware, a device may split a bit component of data that is to be processed into a first bit component and a second bit component, where a sum of a number of bits in the first bit component and a number of bits in the second bit component is equal to a number of bits of the bit component. A first compression unit of the device may process the first bit component and a second compression unit of the device may process the second bit component. Aspects presented herein pertain to improving a compression ratio for non-native compression. A compression ratio may refer to a relative reduction in size of a data representation produced by a data compression algorithm. A compression ratio may be expressed as a quotient of an uncompressed size of data and a compressed size of the data.

In an example with respect to the native compression 402, a device (e.g., the device 104) may obtain image data (e.g., a frame) and the device may divide the image into a plurality of input tiles, where the plurality of input tiles may include an input tile 404. In an example, the input tile 404 may be a rectangular subdivision of the image data (e.g., a rectangular subdivision of the frame).

A component extractor 406 of the device may extract a zeroth bit component 408, a first bit component 410, and an nth bit component 412 from the input tile 404, where n is a positive integer greater than or equal to 2. In an example, each of the zeroth bit component 408, the first bit component 410, and the nth bit component 412 may have a bit width of ten. In an example, the zeroth bit component 408 may correspond to a red (R) value of a pixel, the first bit component 410 may correspond to a green (G) value of the pixel, and the nth bit component 412 may correspond to a blue (B) value of the pixel.

A zeroth compression unit 414 of the device may process the zeroth bit component 408, a first compression unit 416 of the device may process the first bit component 410, and an n−1th compression unit 418 may process the nth bit component 412. For instance, the zeroth compression unit 414 of the device may compress the zeroth bit component 408, the first compression unit 416 of the device may compress first bit component 410, and the n−1th compression unit 418 may compress the nth bit component 412. A sum of bits of the (compressed) zeroth bit component 408, the (compressed) first bit component 410, and the (compressed) nth bit component 412 may be less than a number of bits of the input tile 404. The (compressed) zeroth bit component 408 may be referred to and/or may include a zeroth index 420, the (compressed) first bit component 410 may be referred to and/or may include a first index 422, and the (compressed) nth bit component 412 may be referred to and/or may include an nth index 424.

A packer 426 of the device may pack the zeroth index 420, the first index 422, and the nth index 424 into a bitstream 428. The bitstream 428 may be transmitted to another hardware component within the device or the bitstream may be transmitted to another device.

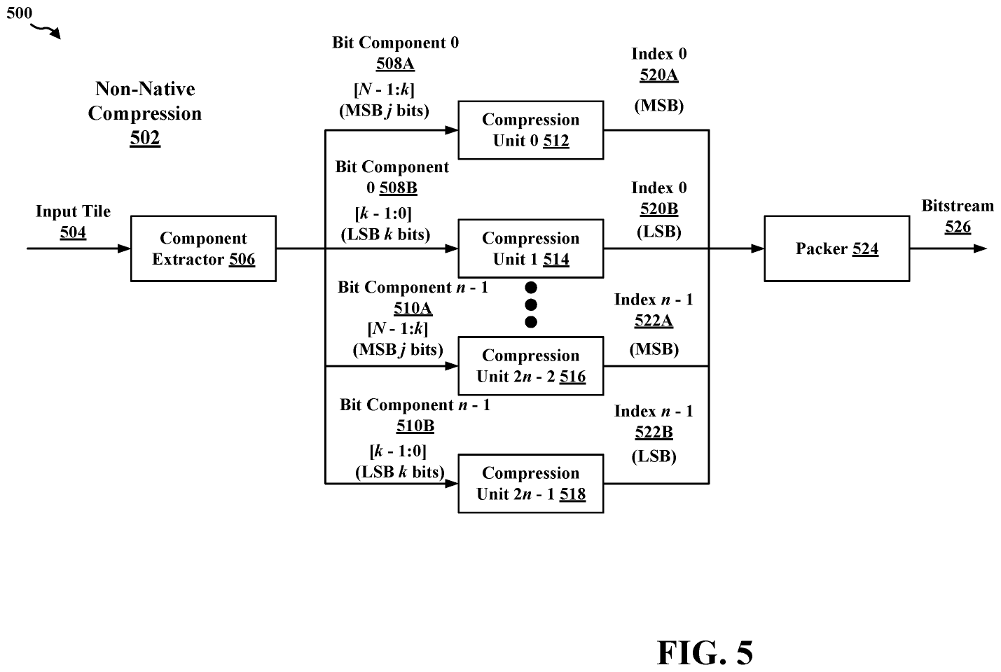

FIG. 5 is a diagram 500 illustrating an example of non-native compression 502 in accordance with one or more techniques of this disclosure. The non-native compression 502 may also be referred to as “non-native encoding.” In an example, the non-native compression 502 may be performed by the device 104. As noted above, hardware complexity in terms of timing and area (i.e., complexity of compression/decompression hardware) may increase for compression/decompression of bit components that have a higher bit width, that is, as a number of bits in a bit component increases, hardware complexity may increase. One way to compress a bit component that has a bit width that is higher than a configured bit width of compression/decompression hardware may be to split the bit component into a first bit component and a second bit component and the compression/decompression hardware may process the first bit component and the second bit component independently using different instances of the same compression hardware (e.g., using a first compression unit and a second compression unit).

In an example with respect to the non-native compression 502, compression/decompression hardware of a device may be configured to process an M bit component (i.e., an M bit pixel component) for compression/decompression purposes, where M is a positive integer. In the example, a compression/decompression format may be defined for processing an N bit component, where N is a positive integer and where N>M. The N bit component may be compressed by the same compression/decompression hardware (i.e., different instances of the same compression/decompression hardware) by splitting the N bit component into j bits that include a most significant bit (MSB) of the N bit component and k bits that include a least significant bit (LSB) of the N bit component, where j and k are positive integers, and where j≤M and k≤M. In an example, N may be sixteen, M may be ten, k may be 8, and j may be 8. An MSB may refer to a bit in a set of bits that represents a highest-order place of a binary integer. An LSB may refer to a bit in a set of bits that represents a lowest-order place of a binary integer. In an example, for a set of “1001,” the MSB may be the leftmost “1” bit and the MSB may be the rightmost “1” bit.

For instance, in the example with respect to the non-native compression 502, a device (e.g., the device 104) may obtain image data (e.g., a frame) and the device may divide the image into a plurality of input tiles, where the plurality of input tiles may include an input tile 504. In an example, the input tile 504 may be a rectangular subdivision of the image data (e.g., a rectangular subdivision of the frame).

A component extractor 506 of the device may extract a zeroth bit component 508A and a zeroth bit component 508B from the input tile 504. The zeroth bit component 508A may correspond to bits [N−1:k] of a zeroth bit component (not illustrated in FIG. 5), that is, the zeroth bit component 508A may include j MSBs of the zeroth bit component. In an example, N may be 16, k may be 8, and j may be 8, and as such, the zeroth bit component 508A may correspond to bits [15:8] of the zeroth bit component and the zeroth bit component 508A may include 8 MSBs of the zeroth bit component. The zeroth bit component 508B may correspond to bits [k−1:0] of the zeroth bit component, that is, the zeroth bit component 508B may include k LSBs of the zeroth bit component. Following the example above, the zeroth bit component 508B may correspond to bits [7:0] of the zeroth bit component and the zeroth bit component 508B may include 8 LSBs of the zeroth bit component. In an example, a combination of the zeroth bit component 508A and the zeroth bit component 508B may correspond to a red (R) value of a pixel.

The component extractor 506 of the device may extract an n−1th bit component 510A and an n−1th bit component 510B from the input tile 504. The n−1th bit component 510A may correspond to bits [N−1:k] of an n−1th bit component (not illustrated in FIG. 5), that is, the n−1th bit component 510A may include j MSBs of the n−1th bit component. In an example, N may be 16, k may be 8, and j may be 8, and as such, the n−1th bit component 510A may correspond to bits [15:8] of the n−1th bit component and the n−1th bit component 510A may include 8 MSBs of the n−1th bit component. The n−1th bit component 510B may correspond to bits [k−1:0] of the n−1th bit component, that is, the n−1th bit component 510B may include k LSBs of the n−1th bit component. Following the example above, the n−1th bit component 510B may correspond to bits [7:0] of the n−1th bit component and the n−1th bit component 510B may include 8 LSBs of the n−1th bit component. In an example, a combination of the n−1th bit component 510A and the n−1th bit component 510B may correspond to a green (G) value of the pixel.

A zeroth compression unit 512 of the device may process the zeroth bit component 508A, a first compression unit 514 of the device may process the zeroth bit component 508B, an 2n−2th compression unit 516 of the device may process the n−1th bit component 510A, and an 2n−1th compression unit 518 of the device may process the n−1th bit component 510B. For instance, the zeroth compression unit 512 of the device may compress the zeroth bit component 508A, the first compression unit 514 of the device may compress the zeroth bit component 508B, the 2n−2th compression unit 516 of the device may compress the n−1th bit component 510A, and the 2n−1th compression unit 518 of the device may compress the n−1th bit component 510B. A sum of bits of the (compressed) zeroth bit component 508A, the (compressed) zeroth bit component 508B, the (compressed) n−1th bit component 510A, and the (compressed) n−1th bit component 510B may be less than a number of bits of the input tile 404. The (compressed) zeroth bit component 508A may be referred to and/or may include a zeroth index 520A corresponding to an MSB of the zeroth bit component, the (compressed) zeroth bit component 508B may be referred to and/or may include a zeroth index 520B corresponding to an LSB of the zeroth bit component, the (compressed) n−1th bit component 510A may be referred to and/or may include an n−1th index 522A corresponding to an MSB of the n−1th bit component, and the (compressed) n−1th bit component 510B may be referred to and/or may include an n−1th index 522B corresponding to an LSB of the n−1th bit component.

A packer 524 of the device may pack the zeroth index 520A, the zeroth index 520B, the n−1th index 522A, and the n−1th index 522B into a bitstream 526. The bitstream 526 may be transmitted to another hardware component within the device or the bitstream may be transmitted to another device.

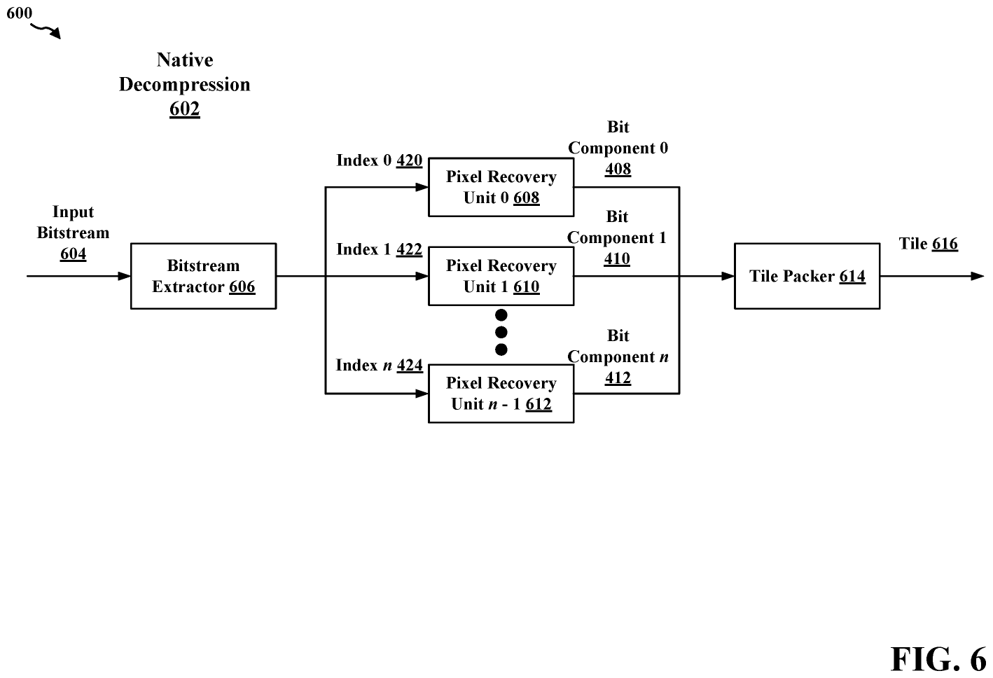

FIG. 6 is a diagram 600 illustrating an example of native decompression 602 in accordance with one or more techniques of this disclosure. The native decompression 602 may also be referred to as “native decoding.” In an example, the native decompression 602 may be performed by the device 104.

A device may obtain an input bitstream 604. In one example, the device may receive the input bitstream 604 from another device. In another example, a hardware component of the device may receive the input bitstream 604 from another hardware component of the device. In an example, the input bitstream 604 may be or include the bitstream 428.

A bitstream extractor 606 of the device may extract the zeroth index 420, the first index 422, and the nth index 424 from the input bitstream 604. A zeroth pixel recovery unit 608 may process the zeroth index 420, a first pixel recovery unit 610 may process the first index 422, and an n−1th pixel recovery unit 612 may process the nth index 424. For instance, the zeroth pixel recovery unit 608 may decompress the zeroth index 420, the first pixel recovery unit 610 may decompress the first index 422, and the n−1th pixel recovery unit 612 may decompress the nth index 424. The aforementioned decompression may reproduce the zeroth bit component 408, the first bit component 410, and the nth bit component 412.

A tile packer 614 of the device may pack the zeroth bit component 408, the first bit component 410, and the nth bit component 412 into a tile 616. In an example, the tile 616 may be or include or may correspond to the input tile 404. In an example, the tile 616 may be part of an image that may be displayed on a display.

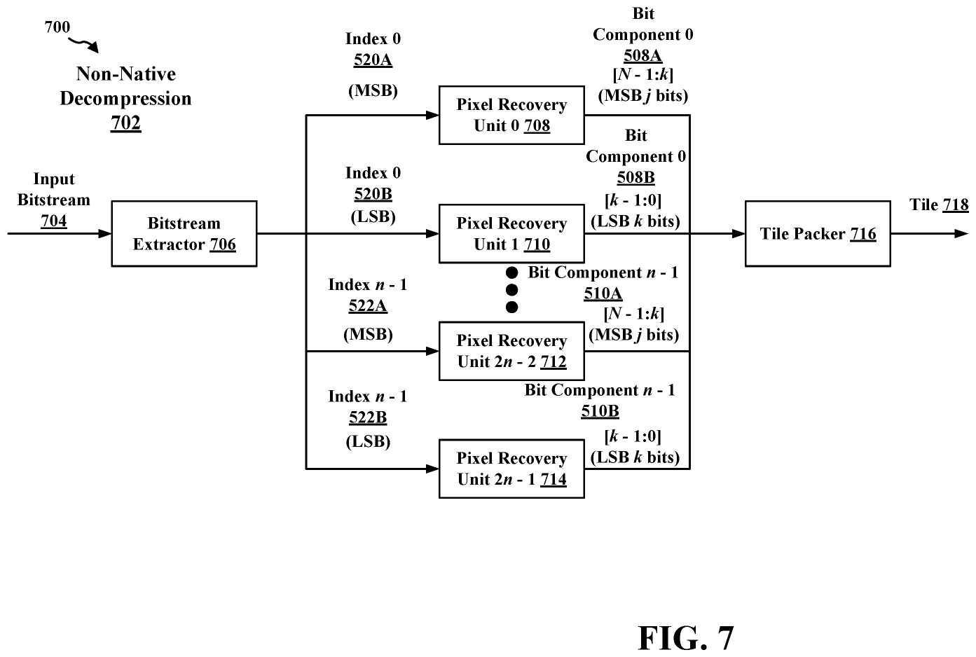

FIG. 7 is a diagram 700 illustrating an example of non-native decompression 702 in accordance with one or more techniques of this disclosure. The non-native decompression 702 may also be referred to as “native decoding.” In an example, the non-native decompression 702 may be performed by the device 104.

A device may obtain an input bitstream 704. In one example, the device may receive the input bitstream 704 from another device. In another example, a hardware component of the device may receive the input bitstream 704 from another hardware component of the device. In an example, the input bitstream 704 may be or include the bitstream 526.

A bitstream extractor 706 may extract the zeroth index 520A, the zeroth index 520B, the n−1th index 522A, and the n−1th index 522B from the input bitstream 704. A zeroth pixel recovery unit 708 may process the zeroth index 520A, a first pixel recovery unit 710 may process the zeroth index 520B, an 2n−2th pixel recovery unit 712 may process the n−1th index 522A, and an 2n−1th pixel recovery unit 714 may process the n−1th index 522B. For instance, the zeroth pixel recovery unit 708 may decompress the zeroth index 520A, the first pixel recovery unit 710 may decompress the zeroth index 520B, the 2n−2th pixel recovery unit 712 may decompress the n−1th index 522A, and the 2n−1th pixel recovery unit 714 may decompress the n−1th index 522B. The aforementioned decompression may reproduce the zeroth bit component 508A, the zeroth bit component 508B, the n−1th bit component 510A, and the n−1th bit component 510B.

A tile packer 716 may pack the zeroth bit component 508A, the zeroth bit component 508B, the n−1th bit component 510A, and the n−1th bit component 510B into a tile 718. In an example, the tile 718 may be or include or may correspond to the input tile 504. In an example, the tile 718 may be part of an image that may be displayed on a display.

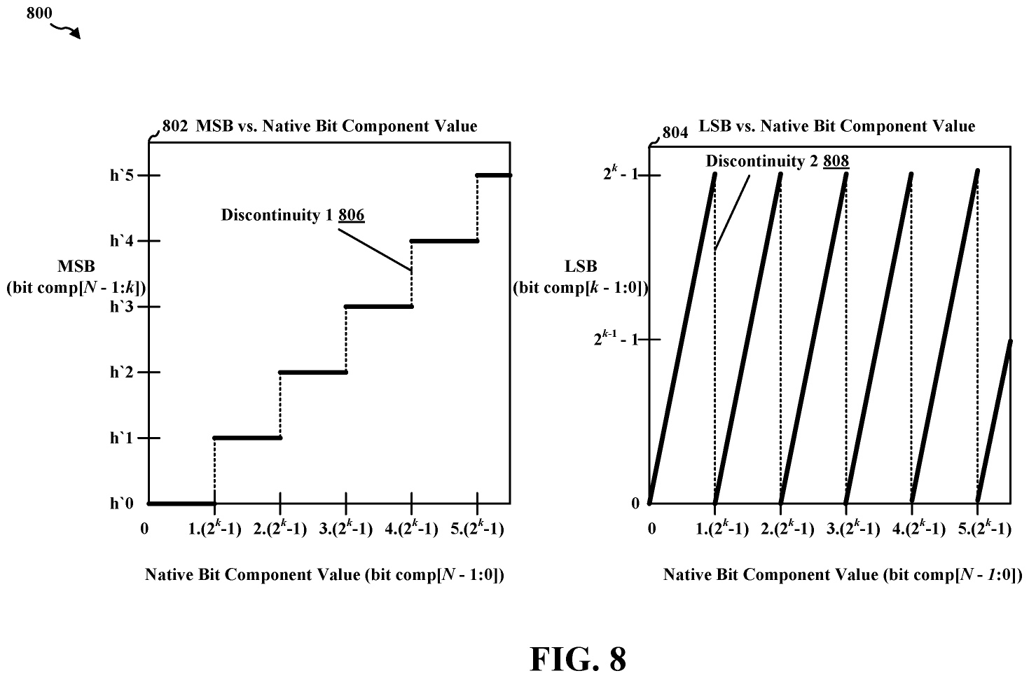

FIG. 8 is a diagram 800 illustrating a first plot 802 of a most significant bit (MSB) versus a native bit component value and a second plot 804 of a least significant bit (LSB) versus a native bit component value in accordance with one or more techniques of this disclosure. The first plot 802 and the second plot 804 may correspond to the non-native compression 502 and the non-native decompression 702 described above.

When a bit component (i.e., a pixel bit component) is predicted non-natively (i.e., by splitting a bit component into separate bit components and compressing the separate bit component independently), a prediction error associated with compression/decompression may be relatively high due to a relatively large discontinuity in LSB values. A discontinuity may refer to a break, a jump, or a gap in a plot of an LSB vs. native bit component value or a break, a jump, or a gap in a plot of an MSB vs. native bit component value. This may cause a reduction in a compression ratio. For instance, the first plot 802 illustrates a first discontinuity 806 (illustrated by a dotted line) associated with MSB values and the second plot 804 illustrates a second discontinuity 808 (illustrated by a dotted line) associated with LSB values. As illustrated in the diagram 800, the second discontinuity 808 may be greater than the first discontinuity 806.

In some aspects, as hardware complexity increases (e.g., timing, area, etc.) for compression of higher bit width components, one way to compress a higher bit width pixel component is by splitting the components and compressing independently using the same hardware (e.g., with small bit width). However, this may cause a prediction error that can be very high at certain ranges. Aspects presented herein may remove the discontinuity in the LSB component using pre-conditioning and performing an LSB folding technique on the split LSB component. In some instances, the MSB may remain the same.

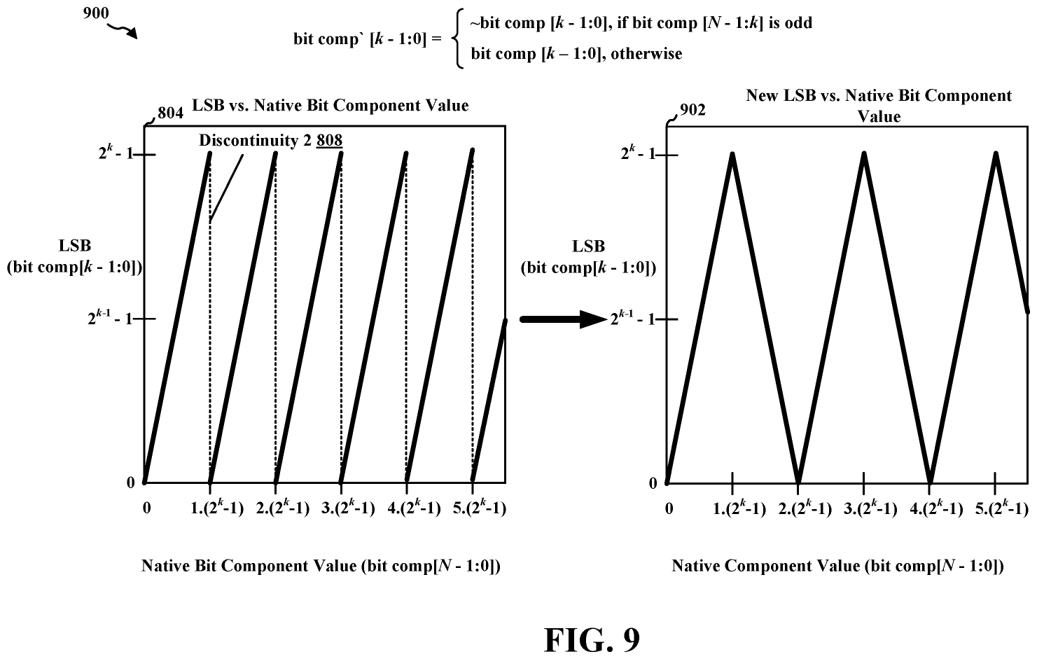

FIG. 9 is a diagram 900 illustrating example aspects pertaining to pixel preconditioning in accordance with one or more techniques of this disclosure. As discussed above, non-native compression/decompression (e.g., the non-native compression 502, the non-native decompression 702) may cause relatively large discontinuities in LSB values, which may reduce a compression ratio. To address this issue, aspects presented herein may remove a discontinuity with respect to an LSB bit component (e.g., the zeroth bit component 508B, the n−1th bit component 510B, etc.). Such a technique that removes the discontinuity may be referred to as “preconditioning,” “pixel preconditioning,” or “LSB folding.” A device (e.g., the device 104) may remove a discontinuity with respect to an LSB bit component according to equation (I) below.

$$bit {comp}^{‵} [ k - 1 : 0 ] = \{ \begin{matrix}\sim bit comp [ k - 1 : 0 ] , if bit comp [ N - 1 : k ] is odd \\ bit comp [ k - 1 : 0 ] , otherwise\end{matrix} \qquad ( I )$$

In equation (I) above, “bit comp [k−1:0]” may refer to an LSB bit component after an LSB associated discontinuity has been removed, “bit component [k−1:0]” may refer to an LSB bit component (e.g., the zeroth bit component 508B, the n−1th bit component 510B) of a bit component, “k” may be the positive integer referred to above, “N” may be the positive integer referred to above, “˜” may refer to a bitwise NOT operation, and “bit comp [N−1:k]” may refer to an MSB bit (e.g., the zeroth bit component 508A, the n−1th bit component 510A) of a bit component. A bitwise NOT operation may refer to switching “1” bits in a sequence of bits to “0” bits and switching “0” bits in the sequence of bits to “1” bits. In an example, performing a bitwise NOT operation on a sequence of bits “0011” may produce a resultant sequence of bits “1100.”

In an example, a compression/decompression format may have a bit width of 16, such as UBWC_P016. In the example, non-native compression/decompression may be performed by dividing the bit width of 16 by 2, resulting in an LSB bit component of 8 bits and an MSB bit component of 8 bits which each may be compressed/decompressed independently. In the example, prediction error may be relatively high for certain pixels having a small difference in value when adjacent pixel values are around a multiple of 256 (e.g., when some pixel values are above, but relatively near a multiple of 256 and when other pixel values are below, but relatively near a multiple of 256). In the example, “k” may be 7 and “N” may be 16, leading to equation (II) below.

$$bit {comp}^{‵} [ 7 : 0 ] = \{ \begin{matrix}\sim bit comp [ 7 : 0 ] , if bit comp [ 15 : 8 ] is odd \\ bit comp [ 7 : 0 ] , otherwise\end{matrix} \qquad ( II )$$

Stated differently, and as reflected in equation (I) above, during a non-native compression process, hardware of a device may extract a bit component from an input tile. As the compression process is non-native, the hardware of the device may further split the bit component into a first bit component (e.g., the zeroth bit component 508B) and a second bit component (the zeroth bit component 508A), where the first bit component may include LSBs of the bit component and where the second bit component may include MSBs of the bit component. The device may determine a parity of the second bit component, that is, the device may determine whether the second bit component represents/corresponds to an even number or an odd number. When the second bit component is odd, the device may perform a bit wise NOT operation on the first bit component as reflected in equation (I). When the second bit component is even, the device may leave the first bit component as the first bit component. In either case, the device may leave the second bit component as the second bit component. Preconditioning the first bit component according to equation (I) may minimize a prediction error when an actual predictor is relatively close to an actual pixel value. The device may then compress the first bit component and the second bit component as described above (e.g., via the zeroth compression unit 512 and the first compression unit 514).

In one aspect, a device (e.g., the device 104) may perform pixel preconditioning according to equation (III) below.

$$bit {comp}^{‵} [ k - 1 : 0 ] = \{ \begin{matrix}\sim bit comp [ k - 1 : 0 ] , if bit comp [ N - 1 : k ] is even \\ bit comp [ k - 1 : 0 ] , otherwise\end{matrix} \qquad ( III )$$

During a non-native decompression process (e.g., the non-native decompression 702), hardware of the device may again apply equation (I) above to the first bit component and the second bit component after the first bit component and the second bit component have been recovered (e.g., via pixel recovery units, such as the zeroth pixel recovery unit 708 and the first pixel recovery unit 710).

The diagram 900 depicts the second plot 804 of the LSB versus the native bit component value described above. The diagram 900 also depicts a plot 902 of a new LSB versus the native bit component value. The plot 902 may correspond to the application of equation (I) above. As illustrated in the plot 902, by applying preconditioning to the LSBs, the second discontinuity 808 is removed. Thus, the preconditioning may increase a compression ratio, which may result in a more efficient use of computing and power resources of a device.

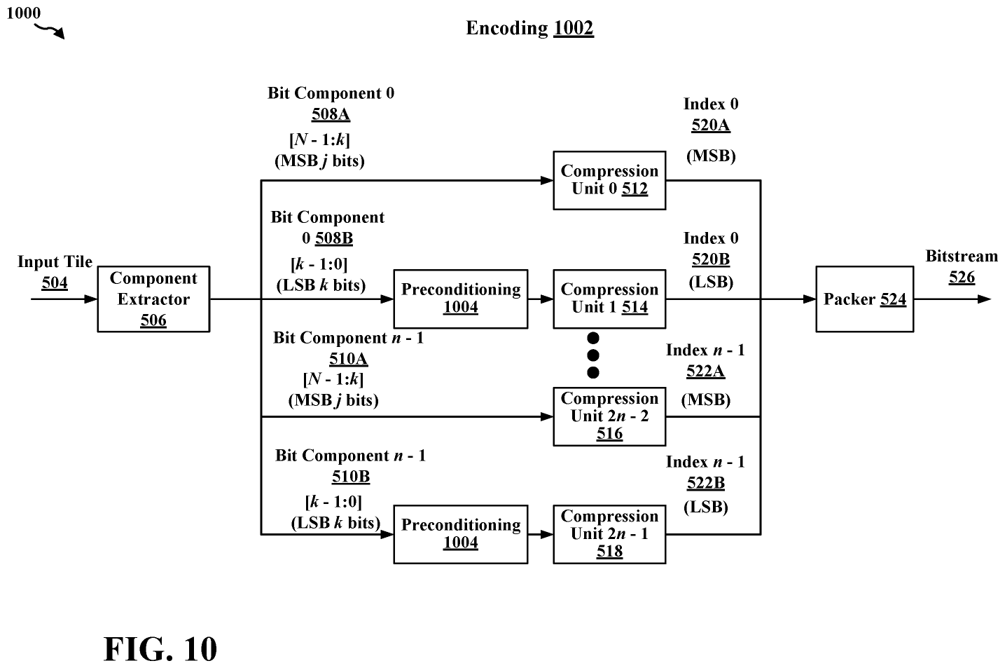

FIG. 10 is a diagram 1000 illustrating example aspects pertaining to encoding 1002 in accordance with one or more techniques of this disclosure. The diagram 1000 illustrates the non-native compression 502 being modified with preconditioning 1004. With more particularity, the device may apply preconditioning 1004 to the zeroth bit component 508B and the n−1th bit component 510B, that is the device may apply equation (I) to the zeroth bit component 508B and the n−1th bit component 510B. Subsequently, the zeroth compression unit 512 may compress the zeroth bit component 508A, the first compression unit 514 may compress the (preconditioned) zeroth bit component 508B, the 2n−2th compression unit 516 may compress the n−1th bit component 510A, and the 2n−1th compression unit 518 may compress the (preconditioned) n−1th bit component 510B.

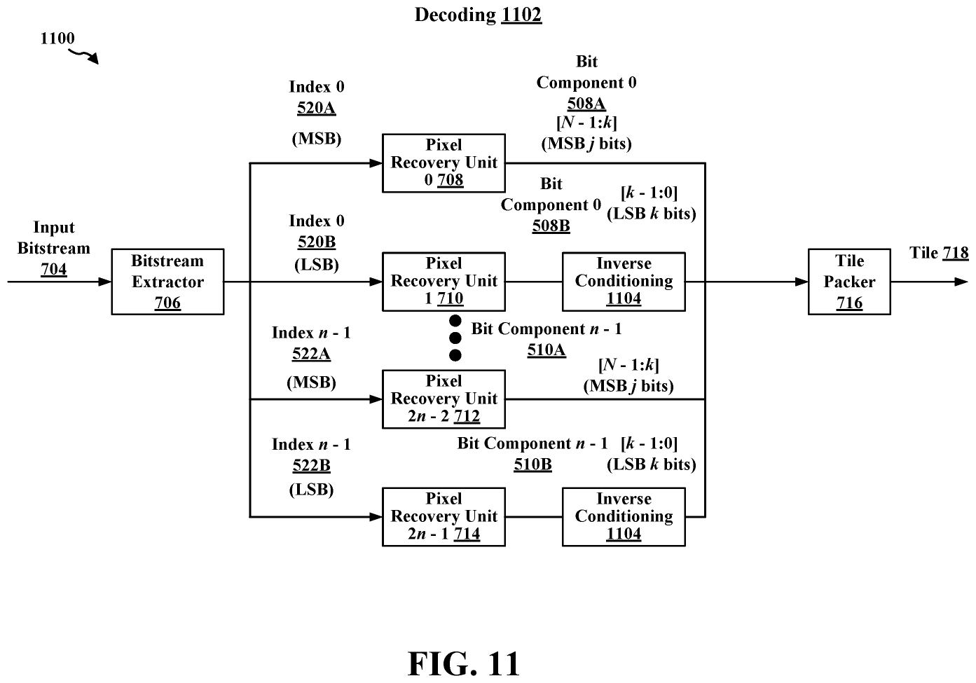

FIG. 11 is a diagram 1100 illustrating example aspects pertaining to decoding 1102 in accordance with one or more techniques of this disclosure. The diagram 1100 illustrates the non-native decompression 702 being modified with inverse conditioning 1104. With more particularity, the device may apply inverse conditioning to the (preconditioned) zeroth bit component 508B and the (preconditioned) n−1th bit component 510B, that is, the device may apply equation (I) to the (preconditioned) zeroth bit component 508B and the (preconditioned) n−1th bit component 510B. Subsequently, the tile packer 716 may pack the zeroth bit component 508A, the (inverse conditioned) zeroth bit component 508B (i.e., the zeroth bit component 508B), the n−1th bit component 510A, and the (inverse conditioned) n−1th bit component 510B (i.e., the n−1th bit component 510B) into the tile 718.

As described above, preconditioning/LSB folding may improve a compression ratio for non-natively compressed tiles with a small area increase in compression/decompression hardware. In an example, when preconditioning/LSB folding is applied to a P016 tile (16-bit component), compression ratio (CR) improvements may be observed in comparison to a non-native compression method that does not use preconditioning/LSB folding. Table 1 and Table 2 below detail aspects pertaining to improvements in CR provided by preconditioning/LSB folding.

TABLE 1
Preconditioning CR Improvements

| | | | | 6 MSB + 10 LSB |
|---|---|---|---|---|
| | Native 16B | Non-native | 8B LSB | Split with LSB |
| | CR | (8 + 8) CR | Folded CR | Folding |
| Max | 6.144 | 5.993 | 6.023 | 6.045 |
| Min | 1.863 | 1.715 | 1.744 | 1.79 |
| Avg | 5.061792035 | 4.895424779 | 4.902057522 | 4.965070796 |
| Practical | 2.44122 | 2.25146 | 2.28446 | 2.27473 |
| Worst | | | | |
| Case | | | | |
| (PWC) | | | | |

TABLE 2
Preconditioning CR Improvement Differences

| | CR Diff | CR Diff | CR Diff | CR Diff |
|---|---|---|---|---|
| | (8B LSB | (16B − 8B | (16B − | (6 MSB − 8 |
| | Folding − 8B)% | LSB Folding)% | 8B)% | LSB Folding)% |
| Max | 2.374169041 | 8.582524272 | 9.992132179 | 3.839055002 |
| Min | 0.216450216 | 0.600446046 | 1.189860321 | −1.699586587 |
| Avg | 0.929447189 | 3.702327818 | 4.669366292 | 1.497897987 |
| PWC | 0.2519953 | 0.66299249 | 1.200222027 | −0.153962461 |

As illustrated in Table 1 and Table 2 above, for a bit component that is split by 8 MSBs and 8 LSBs and that undergoes preconditioning as described above, a CR improvement of ˜0.93% may be observed. For a bit component that is split by 6 MSBs and 10 LSBs, a ˜2.3% CR improvement may be observed. The preconditioning may cause a minimal area increase (e.g., ˜0.3%) in compression/decompression hardware.

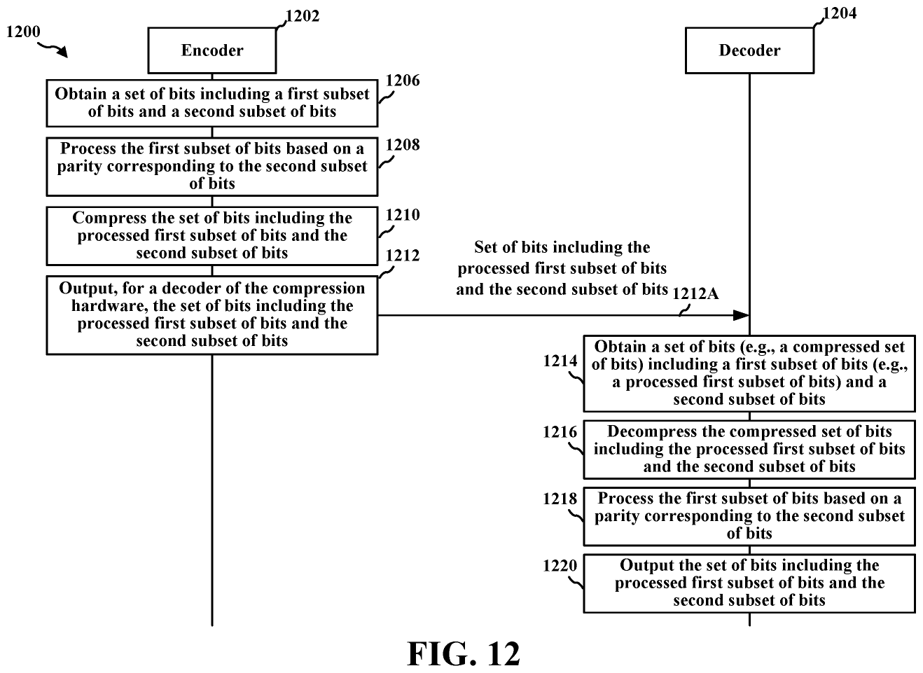

FIG. 12 is a call flow diagram 1200 illustrating example communications between an encoder 1202 and a decoder 1204 in accordance with one or more techniques of this disclosure. The encoder 1202 may be implemented in hardware and/or software. The decoder 1204 may be implemented in hardware and/or software. In an example, the encoder 1202 and/or the decoder 1204 may be included in the device 104. In another example, the encoder 1202 and the decoder 1204 may be included in different devices.

At 1206, the encoder 1202 may obtain a set of bits including a first subset of bits and a second subset of bits, where a bit width of the set of bits is greater than a configured bit width of compression hardware. At 1208, the encoder 1202 may process the first subset of bits based on a parity corresponding to the second subset of bits. At 1212, the encoder 1202 may output, for a decoder (e.g., the decoder 1204) of the compression hardware, the set of bits including the processed first subset of bits and the second subset of bits. For instance, at 1212A, the encoder 1202 may transmit, for the decoder, the set of bits including the processed first subset of bits and the second subset of bits. At 1210, the encoder 1202 may compress the set of bits including the processed first subset of bits and the second subset of bits, where outputting the set of bits including the processed first subset of bits and the second subset of bits at 1212 may include outputting, to the decoder (e.g., the decoder 1204) of the compression hardware, the compressed set of bits.

At 1214, the decoder 1204 may obtain, from an encoder (e.g., the encoder 1202) of compression hardware, a set of bits including a first subset of bits and a second subset of bits, where a bit width of the set of bits is greater than a configured bit width of the compression hardware. At 1218, the decoder 1204 may process the first subset of bits based on a parity corresponding to the second subset of bits. At 1220, the decoder 1204 may output the set of bits including the processed first subset of bits and the second subset of bits. In one aspect, obtaining the set of bits including the processed first subset of bits and the second subset of bits may include receiving, at 1612A, a compressed set of bits including the processed first subset of bits and the second subset of bits, and at 1216, the decoder 1204 may decompress the compressed set of bits including the processed first subset of bits and the second subset of bits, where processing the first subset of bits based on the parity corresponding to the second subset of bits at 1218 may include processing the decompressed first subsets of bits based on the parity corresponding to the decompressed second subset of bits.

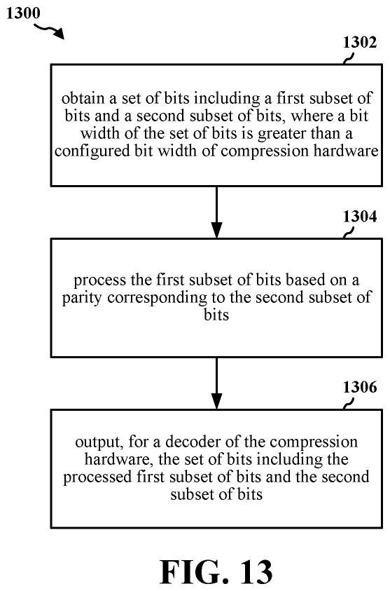

FIG. 13 is a flowchart 1300 of an example method of graphics processing in accordance with one or more techniques of this disclosure. The method may be performed by an apparatus, such as an apparatus for graphics processing, a GPU, a CPU, the device 104, the encoder 1202, a wireless communication device, and the like, as used in connection with the aspects of FIGS. 1-12. The method may be associated with various advantages at the apparatus, such as improving a compression ratio and conserving computing resources. In an example, the method may be performed by the compressor 198.

At 1302, the apparatus (e.g., an encoder) obtains a set of bits including a first subset of bits and a second subset of bits, where a bit width of the set of bits is greater than a configured bit width of compression hardware. For example, FIG. 12 at 1206 shows that the encoder 1202 may obtain a set of bits including a first subset of bits and a second subset of bits, where a bit width of the set of bits may be greater than a configured bit width of compression hardware. In an example, the set of bits may include the zeroth bit component 508A, the zeroth bit component 508B, the n−1th bit component 510A, and the n−1th bit component 510B. In an example, the first subset of bits may correspond to the zeroth bit component 508B and the second subset of bits may correspond to the zeroth bit component 508A. In an example, the compression hardware may be or include the zeroth compression unit 512 or the first compression unit 514. In an example, 1302 may be performed by the compressor 198.

At 1304, the apparatus (e.g., an encoder) processes the first subset of bits based on a parity corresponding to the second subset of bits. For example, FIG. 12 at 1208 shows that the encoder 1202 may process the first subset of bits based on a parity corresponding to the second subset of bits. In an example, processing the first subset of bits based on a parity corresponding to the second subset of bits may correspond to the preconditioning 1004. In another example, processing the first subset of bits based on a parity corresponding to the second subset of bits may correspond to equation (I) or equation (II) above. In an example, 1304 may be performed by the compressor 198.

At 1306, the apparatus (e.g., an encoder) outputs, for a decoder of the compression hardware, the set of bits including the processed first subset of bits and the second subset of bits. For example, FIG. 12 at 1212 shows that the encoder 1202 may output, for a decoder (e.g., the decoder 1204) of the compression hardware, the set of bits including the processed first subset of bits and the second subset of bits. In an example, outputting the set of bits may correspond to the bitstream 526. In an example, 1306 may be performed by the compressor 198.

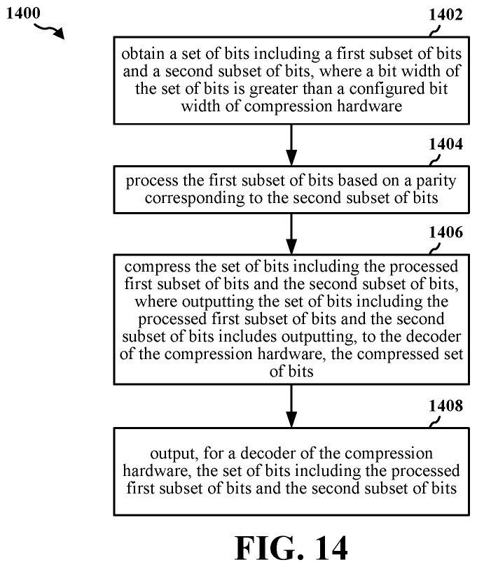

FIG. 14 is a flowchart 1400 of an example method of graphics processing in accordance with one or more techniques of this disclosure. The method may be performed by an apparatus, such as an apparatus for graphics processing, a GPU, a CPU, the device 104, the encoder 1202, a wireless communication device, and the like, as used in connection with the aspects of FIGS. 1-12. The method may be associated with various advantages at the apparatus, such as improving a compression ratio and conserving computing resources. In an example, the method (including the various aspects detailed below) may be performed by the compressor 198.

At 1402, the apparatus (e.g., an encoder) obtains a set of bits including a first subset of bits and a second subset of bits, where a bit width of the set of bits is greater than a configured bit width of compression hardware. In an example, the set of bits may include the zeroth bit component 508A, the zeroth bit component 508B, the n−1th bit component 510A, and the n−1th bit component 510B. In an example, the first subset of bits may correspond to the zeroth bit component 508B and the second subset of bits may correspond to the zeroth bit component 508A. In an example, the compression hardware may be or include the zeroth compression unit 512 or the first compression unit 514. In an example, 1402 may be performed by the compressor 198.

At 1404, the apparatus (e.g., an encoder) processes the first subset of bits based on a parity corresponding to the second subset of bits. For example, FIG. 12 at 1208 shows that the encoder 1202 may process the first subset of bits based on a parity corresponding to the second subset of bits. In an example, processing the first subset of bits based on a parity corresponding to the second subset of bits may correspond to the preconditioning 1004. In another example, processing the first subset of bits based on a parity corresponding to the second subset of bits may correspond to equation (I) or equation (II) above. In an example, 1404 may be performed by the compressor 198.

At 1408, the apparatus (e.g., an encoder) outputs, for a decoder of the compression hardware, the set of bits including the processed first subset of bits and the second subset of bits. For example, FIG. 12 at 1212 shows that the encoder 1202 may output, for a decoder (e.g., the decoder 1204) of the compression hardware, the set of bits including the processed first subset of bits and the second subset of bits. In an example, outputting the set of bits may correspond to the bitstream 526. In an example, 1408 may be performed by the compressor 198.

In one aspect, the parity corresponding to the second subset of bits may indicate an odd number, and processing the first subset of bits may include performing a bitwise NOT operation on the first subset of bits. For example, the aforementioned aspect may correspond to ˜bit comp [k−1:0], if bit comp [N−1:k] is odd in equation (I) or ˜bit comp [7:0], if bit comp [15:8] is odd in equation (II). In an example, processing the first subset of bits at 1208 may include performing a bitwise NOT operation on the first subset of bits.

In one aspect, the parity corresponding to the second subset of bits may indicate an even number, and processing the first subset of bits may include refraining to adjust the first subset of bits. For example, the aforementioned aspect may correspond to bit comp [k−1:0], otherwise in equation (I) or bit comp [7:0], otherwise in equation (II). In an example, processing the first subset of bits at 1208 may include refraining to adjust the first subset of bits.

In one aspect, the first subset of bits may correspond to a least significant bit (LSB) component of the set of bits, and the second subset of bits may correspond to a most significant bit (MSB) component of the set of bits. For example, FIG. 10 shows that the zeroth bit component 508B may correspond to an LSB component of the set of bits and that the zeroth bit component 508A may correspond to an MSB component of the set of bits.

In one aspect, processing the first subset of bits may remove a discontinuity associated with the LSB component. For example, processing the first subset of bits at 1208 may remove a discontinuity associated with the LSB component. In an example, the discontinuity may be or include the second discontinuity 808.

In one aspect, the set of bits may correspond to a set of pixels in a frame. For example, the set of bits obtained at 1206 may correspond to a set of pixels in a frame.

In one aspect, outputting the set of bits including the processed first subset of bits and the second subset of bits may include transmitting, to the decoder of the compression hardware, the set of bits including the processed first subset of bits and the second subset of bits. For example, FIG. 12 at 1612A shows that outputting the set of bits including the processed first subset of bits and the second subset of bits may include transmitting, to the decoder (e.g., the decoder 1204) of the compression hardware, the set of bits including the processed first subset of bits and the second subset of bits.

In one aspect, at 1406, the apparatus (e.g., an encoder) may compress the set of bits including the processed first subset of bits and the second subset of bits, where outputting the set of bits including the processed first subset of bits and the second subset of bits may include outputting, to the decoder of the compression hardware, the compressed set of bits. For example, FIG. 12 at 1210 shows that the encoder 1202 may compress the set of bits including the processed first subset of bits and the second subset of bits, where outputting the set of bits including the processed first subset of bits and the second subset of bits at 1212 may include outputting, to the decoder of the compression hardware, the compressed set of bits. In an example, compressing the set of bits may be associated with the zeroth compression unit 512 and the first compression unit 514 in FIG. 10. In an example, 1406 may be performed by the compressor 198.

In one aspect, the bit width of the set of bits may be 10 bits, 12 bits, 14 bits, or 16 bits. For example, the bit width of the set of bits obtained at 1206 may be 10 bits, 12 bits, 14 bits, or 16 bits.

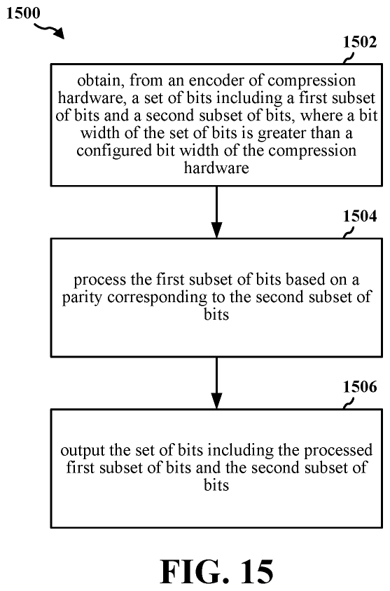

FIG. 15 is a flowchart 1500 of an example method of graphics processing in accordance with one or more techniques of this disclosure. The method may be performed by an apparatus, such as an apparatus for graphics processing, a GPU, a CPU, the device 104, the decoder 1204, a wireless communication device, and the like, as used in connection with the aspects of FIGS. 1-12. The method may be associated with various advantages at the apparatus, such as improving a compression ratio and conserving computing resources. In an example, the method may be performed by the decompressor 199.

At 1502, the apparatus (e.g., a decoder) obtains, from an encoder of compression hardware, a set of bits including a first subset of bits and a second subset of bits, where a bit width of the set of bits is greater than a configured bit width of the compression hardware. For example, FIG. 12 at 1214 shows that the decoder 1204 may obtain, from an encoder (e.g., the encoder 1202) of compression hardware, a set of bits including a first subset of bits and a second subset of bits, where a bit width of the set of bits is greater than a configured bit width of the compression hardware. In an example, the set of bits may correspond to the zeroth index 520A, the zeroth index 520B, the n−1th index 522A, or the n−1th index 522B. In an example, the first subset of bits may correspond to the zeroth index 520B and the second subset of bits may correspond to the zeroth index 520A. In an example, the compression hardware may be or include the zeroth pixel recovery unit 708 and/or the first pixel recovery unit 710. In an example, 1502 may be performed by the decompressor 199.

At 1504, the apparatus (e.g., a decoder) processes the first subset of bits based on a parity corresponding to the second subset of bits. For example, FIG. 12 at 1218 shows that the decoder 1204 may process the first subset of bits based on a parity corresponding to the second subset of bits. In an example, processing the first subset of bits based on a parity corresponding to the second subset of bits may correspond to the inverse conditioning 1104. In another example, processing the first subset of bits based on a parity corresponding to the second subset of bits may correspond to equation (I) or equation (II) above. In an example, processing the first subset of bits based on the parity corresponding to the second subset of bits may generate the zeroth bit component 508A and the zeroth bit component 508B. In an example, 1504 may be performed by the decompressor 199.

At 1506, the apparatus (e.g., a decoder) outputs the set of bits including the processed first subset of bits and the second subset of bits. For example, FIG. 12 at 1220 shows that the decoder 1204 may output the set of bits including the processed first subset of bits and the second subset of bits. In an example, outputting the set of bits may correspond to the tile 718. In an example, 1506 may be performed by the decompressor 199.

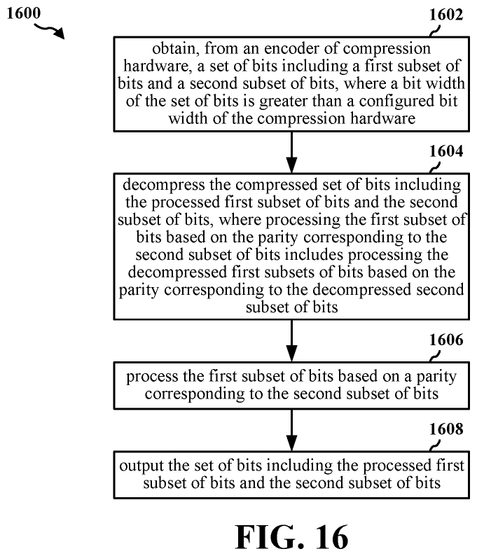

FIG. 16 is a flowchart 1600 of an example method of graphics processing in accordance with one or more techniques of this disclosure. The method may be performed by an apparatus, such as an apparatus for graphics processing, a GPU, a CPU, the device 104, the decoder 1204, a wireless communication device, and the like, as used in connection with the aspects of FIGS. 1-12. The method may be associated with various advantages at the apparatus, such as improving a compression ratio and conserving computing resources. In an example, the method (including the various aspects detailed below) may be performed by the decompressor 199.

At 1602, the apparatus (e.g., a decoder) obtains, from an encoder of compression hardware, a set of bits including a first subset of bits and a second subset of bits, where a bit width of the set of bits is greater than a configured bit width of the compression hardware. For example, FIG. 12 at 1214 shows that the decoder 1204 may obtain, from an encoder (e.g., the encoder 1202) of compression hardware, a set of bits including a first subset of bits and a second subset of bits, where a bit width of the set of bits is greater than a configured bit width of the compression hardware. In an example, the set of bits may correspond to the zeroth index 520A, the zeroth index 520B, the n−1th index 522A, or the n−1th index 522B. In an example, the first subset of bits may correspond to the zeroth index 520B and the second subset of bits may correspond to the zeroth index 520A. In an example, the compression hardware may be or include the zeroth pixel recovery unit 708 and/or the first pixel recovery unit 710. In an example, 1602 may be performed by the decompressor 199.

At 1606, the apparatus (e.g., a decoder) processes the first subset of bits based on a parity corresponding to the second subset of bits. For example, FIG. 12 at 1218 shows that the decoder 1204 may process the first subset of bits based on a parity corresponding to the second subset of bits. In an example, processing the first subset of bits based on a parity corresponding to the second subset of bits may correspond to the inverse conditioning 1104. In another example, processing the first subset of bits based on a parity corresponding to the second subset of bits may correspond to equation (I) or equation (II) above. In an example, processing the first subset of bits based on the parity corresponding to the second subset of bits may generate the zeroth bit component 508A and the zeroth bit component 508B. In an example, 1606 may be performed by the decompressor 199.

At 1608, the apparatus (e.g., a decoder) outputs the set of bits including the processed first subset of bits and the second subset of bits. For example, FIG. 12 at 1220 shows that the decoder 1204 may output the set of bits including the processed first subset of bits and the second subset of bits. In an example, outputting the set of bits may correspond to the tile 718. In an example, 1608 may be performed by the decompressor 199.

In one aspect, the parity corresponding to the second subset of bits may indicate an odd number, and processing the first subset of bits may include performing a bitwise NOT operation on the first subset of bits. For example, the aforementioned aspect may correspond to ˜bit comp [k−1:0], if bit comp [N−1:k] is odd in equation (I) or ˜bit comp [7:0], if bit comp [15:8] is odd in equation (II). In an example, processing the first subset of bits at 1218 may include performing a bitwise NOT operation on the first subset of bits.

In one aspect, the parity corresponding to the second subset of bits may indicate an even number, and processing the first subset of bits may include refraining to adjust the first subset of bits. For example, the aforementioned aspect may correspond to bit comp [k−1:0], otherwise in equation (I) or bit comp [7:0], otherwise in equation (II). In an example, processing the first subset of bits at 1218 may include refraining to adjust the first subset of bits.

In one aspect, the first subset of bits may correspond to a least significant bit (LSB) component of the set of bits, and the second subset of bits may correspond to a most significant bit (MSB) component of the set of bits. For example, FIG. 10 shows that the zeroth index 520B may correspond to an LSB component of the set of bits and that the zeroth index 520A may correspond to an MSB component of the set of bits.

In one aspect, the set of bits may correspond to a set of pixels in a frame. For example, the set of bits obtained at 1214 may correspond to a set of pixels in a frame.

In one aspect, outputting the set of bits including the processed first subset of bits and the second subset of bits may include: transmitting the set of bits to a display; or storing the set of bits in at least one of a memory, a buffer, or a cache. For example, outputting the set of bits including the processed first subset of bits and the second subset of bits at 1220 may include: transmitting the set of bits to a display (e.g., the display(s) 131) or storing the set of bits in at least one of a memory, a buffer, or a cache.

In one aspect, obtaining the set of bits including the processed first subset of bits and the second subset of bits may include receiving a compressed set of bits including the processed first subset of bits and the second subset of bits, and at 1604, the apparatus (e.g., a decoder) may decompress the compressed set of bits including the processed first subset of bits and the second subset of bits, where processing the first subset of bits based on the parity corresponding to the second subset of bits may include processing the decompressed first subsets of bits based on the parity corresponding to the decompressed second subset of bits. For example, obtaining the set of bits including the processed first subset of bits and the second subset of bits at 1214 may include receiving (e.g., from the encoder 1202) a compressed set of bits including the processed first subset of bits and the second subset of bits. For example, FIG. 12 at 1216 shows that the decoder 1204 may decompress the compressed set of bits including the processed first subset of bits and the second subset of bits, where processing the first subset of bits based on the parity corresponding to the second subset of bits at 1218 may include processing the decompressed first subsets of bits based on the parity corresponding to the decompressed second subset of bits. In an example, the aforementioned aspect may correspond to the zeroth pixel recovery unit 708 and/or the first pixel recovery unit 710. In an example, 1604 may be performed by the decompressor 199.

In one aspect, the bit width of the set of bits may be 10 bits, 12 bits, 14 bits, or 16 bits. For example, the bit width of the set of bits obtained at 1214 may be 10 bits, 12 bits, 14 bits, or 16 bits.

In configurations, a method or an apparatus for graphics processing is provided. The apparatus may be a GPU, a CPU, or some other processor that may perform graphics processing. In aspects, the apparatus may be the processing unit 120 within the device 104, or may be some other hardware within the device 104 or another device. The apparatus may include means for obtaining a set of bits including a first subset of bits and a second subset of bits, where a bit width of the set of bits is greater than a configured bit width of compression hardware. The apparatus may further include means for processing the first subset of bits based on a parity corresponding to the second subset of bits. The apparatus may further include means for outputting, for a decoder of the compression hardware, the set of bits including the processed first subset of bits and the second subset of bits. The apparatus may further include means for compressing the set of bits including the processed first subset of bits and the second subset of bits, where outputting the set of bits including the processed first subset of bits and the second subset of bits includes outputting, to the decoder of the compression hardware, the compressed set of bits.

In configurations, a method or an apparatus for graphics processing is provided. The apparatus may be a GPU, a CPU, or some other processor that may perform graphics processing. In aspects, the apparatus may be the processing unit 120 within the device 104, or may be some other hardware within the device 104 or another device. The apparatus may include means for obtaining, from an encoder of compression hardware, a set of bits including a first subset of bits and a second subset of bits, where a bit width of the set of bits is greater than a configured bit width of the compression hardware. The apparatus may further include means for processing the first subset of bits based on a parity corresponding to the second subset of bits. The apparatus may further include means for outputting the set of bits including the processed first subset of bits and the second subset of bits. The apparatus may further include means for decompressing the compressed set of bits including the processed first subset of bits and the second subset of bits, where processing the first subset of bits based on the parity corresponding to the second subset of bits includes processing the decompressed first subsets of bits based on the parity corresponding to the decompressed second subset of bits.

It is understood that the specific order or hierarchy of blocks/steps in the processes, flowcharts, and/or call flow diagrams disclosed herein is an illustration of example approaches. Based upon design preferences, it is understood that the specific order or hierarchy of the blocks/steps in the processes, flowcharts, and/or call flow diagrams may be rearranged. Further, some blocks/steps may be combined and/or omitted. Other blocks/steps may also be added. The accompanying method claims present elements of the various blocks/steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language of the claims, where reference to an element in the singular is not intended to mean “one and only one” unless specifically so stated, but rather “one or more.” The word “exemplary” is used herein to mean “serving as an example, instance, or illustration.” Any aspect described herein as “exemplary” is not necessarily to be construed as preferred or advantageous over other aspects.

Unless specifically stated otherwise, the term “some” refers to one or more and the term “or” may be interpreted as “and/or” where context does not dictate otherwise. Combinations such as “at least one of A, B, or C,” “one or more of A, B, or C,” “at least one of A, B, and C,” “one or more of A, B, and C,” and “A, B, C, or any combination thereof” include any combination of A, B, and/or C, and may include multiples of A, multiples of B, or multiples of C. Specifically, combinations such as “at least one of A, B, or C,” “one or more of A, B, or C,” “at least one of A, B, and C,” “one or more of A, B, and C,” and “A, B, C, or any combination thereof” may be A only, B only, C only, A and B, A and C, B and C, or A and B and C, where any such combinations may contain one or more member or members of A, B, or C. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. The words “module,” “mechanism,” “element,” “device,” and the like may not be a substitute for the word “means.” As such, no claim element is to be construed as a means plus function unless the element is expressly recited using the phrase “means for.” Unless stated otherwise, the phrase “a processor” may refer to “any of one or more processors” (e.g., one processor of one or more processors, a number (greater than one) of processors in the one or more processors, or all of the one or more processors) and the phrase “a memory” may refer to “any of one or more memories” (e.g., one memory of one or more memories, a number (greater than one) of memories in the one or more memories, or all of the one or more memories).

In one or more examples, the functions described herein may be implemented in hardware, software, firmware, or any combination thereof. For example, although the term “processing unit” has been used throughout this disclosure, such processing units may be implemented in hardware, software, firmware, or any combination thereof. If any function, processing unit, technique described herein, or other module is implemented in software, the function, processing unit, technique described herein, or other module may be stored on or transmitted over as one or more instructions or code on a computer-readable medium.

Computer-readable media may include computer data storage media or communication media including any medium that facilitates transfer of a computer program from one place to another. In this manner, computer-readable media generally may correspond to: (1) tangible computer-readable storage media, which is non-transitory; or (2) a communication medium such as a signal or carrier wave. Data storage media may be any available media that can be accessed by one or more computers or one or more processors to retrieve instructions, code, and/or data structures for implementation of the techniques described in this disclosure. By way of example, and not limitation, such computer-readable media may include RAM, ROM, EEPROM, compact disc-read only memory (CD-ROM), or other optical disk storage, magnetic disk storage, or other magnetic storage devices. Disk and disc, as used herein, includes compact disc (CD), laser disc, optical disc, digital versatile disc (DVD), floppy disk, and Blu-ray disc, where disks usually reproduce data magnetically, while discs usually reproduce data optically with lasers. Combinations of the above should also be included within the scope of computer-readable media. A computer program product may include a computer-readable medium.

The techniques of this disclosure may be implemented in a wide variety of devices or apparatuses, including a wireless handset, an integrated circuit (IC) or a set of ICs, e.g., a chip set. Various components, modules or units are described in this disclosure to emphasize functional aspects of devices configured to perform the disclosed techniques, but do not necessarily need realization by different hardware units. Rather, as described above, various units may be combined in any hardware unit or provided by a collection of inter-operative hardware units, including one or more processors as described above, in conjunction with suitable software and/or firmware. Accordingly, the term “processor,” as used herein may refer to any of the foregoing structure or any other structure suitable for implementation of the techniques described herein. Also, the techniques may be fully implemented in one or more circuits or logic elements.

The following aspects are illustrative only and may be combined with other aspects or teachings described herein, without limitation.

Aspect 1 is a method of data processing, including: obtaining a set of bits including a first subset of bits and a second subset of bits, wherein a bit width of the set of bits is greater than a configured bit width of compression hardware; processing the first subset of bits based on a parity corresponding to the second subset of bits; and outputting, for a decoder of the compression hardware, the set of bits including the processed first subset of bits and the second subset of bits.

Aspect 2 may be combined with aspect 1, wherein the parity corresponding to the second subset of bits indicates an odd number, and wherein processing the first subset of bits includes performing a bitwise NOT operation on the first subset of bits.

Aspect 3 may be combined with aspect 1, wherein the parity corresponding to the second subset of bits indicates an even number, and wherein processing the first subset of bits includes refraining from adjusting the first subset of bits.

Aspect 4 may be combined with any of aspects 1-3, wherein the first subset of bits corresponds to a least significant bit (LSB) component of the set of bits, and wherein the second subset of bits corresponds to a most significant bit (MSB) component of the set of bits.

Aspect 5 may be combined with aspect 4, wherein processing the first subset of bits removes a discontinuity associated with the LSB component.

Aspect 6 may be combined with any of aspects 1-5, wherein the set of bits corresponds to a set of pixels in a frame.

Aspect 7 may be combined with any of aspects 1-6, wherein outputting the set of bits including the processed first subset of bits and the second subset of bits includes transmitting, to the decoder of the compression hardware, the set of bits including the processed first subset of bits and the second subset of bits.

Aspect 8 may be combined with any of aspects 1-7, further including: compressing the set of bits including the processed first subset of bits and the second subset of bits, wherein outputting the set of bits including the processed first subset of bits and the second subset of bits includes outputting, to the decoder of the compression hardware, the compressed set of bits.

Aspect 9 may be combined with any of aspects 1-8, wherein the bit width of the set of bits is 10 bits, 12 bits, 14 bits, or 16 bits.

Aspect 10 is an apparatus for data processing including a processor coupled to a memory and, based on information stored in the memory, the processor is configured to implement a method as in any of aspects 1-9.

Aspect 11 may be combined with aspect 10 and includes that the apparatus is a wireless communication device comprising at least one of a transceiver or an antenna coupled to the processor, wherein to output the set of bits, the processor is configured to output the set of bits via at least one of the transceiver or the antenna.

Aspect 12 is an apparatus for data processing including means for implementing a method as in any of aspects 1-9.

Aspect 13 is a computer-readable medium (e.g., a non-transitory computer-readable medium) storing computer executable code, the computer executable code, when executed by a processor, causes the processor to implement a method as in any of aspects 1-9.

Aspect 14 is a method of data processing, including: obtaining, from an encoder of compression hardware, a set of bits including a first subset of bits and a second subset of bits, wherein a bit width of the set of bits is greater than a configured bit width of the compression hardware; processing the first subset of bits based on a parity corresponding to the second subset of bits; and outputting the set of bits including the processed first subset of bits and the second subset of bits.

Aspect 15 may be combined with aspect 14, wherein the parity corresponding to the second subset of bits indicates an odd number, and wherein processing the first subset of bits includes performing a bitwise NOT operation on the first subset of bits.

Aspect 16 may be combined with aspect 14, wherein the parity corresponding to the second subset of bits indicates an even number, and wherein processing the first subset of bits includes refraining from adjusting the first subset of bits.

Aspect 17 may be combined with any of aspects 14-16, wherein the first subset of bits corresponds to a least significant bit (LSB) component of the set of bits, and wherein the second subset of bits corresponds to a most significant bit (MSB) component of the set of bits.

Aspect 18 may be combined with any of aspects 14-17, wherein the set of bits corresponds to a set of pixels in a frame.

Aspect 19 may be combined with any of aspects 14-18, wherein outputting the set of bits including the processed first subset of bits and the second subset of bits includes: transmitting the set of bits to a display; or storing the set of bits in at least one of a memory, a buffer, or a cache.

Aspect 20 may be combined with any of aspects 14-19, wherein obtaining the set of bits including the processed first subset of bits and the second subset of bits includes receiving a compressed set of bits including the processed first subset of bits and the second subset of bits, the method further including: decompressing the compressed set of bits including the processed first subset of bits and the second subset of bits, wherein processing the first subset of bits based on the parity corresponding to the second subset of bits includes processing the decompressed first subsets of bits based on the parity corresponding to the decompressed second subset of bits.

Aspect 21 may be combined with any of aspects 14-20, wherein the bit width of the set of bits is 10 bits, 12 bits, 14 bits, or 16 bits.

Aspect 22 is an apparatus for data processing including a processor coupled to a memory and, based on information stored in the memory, the processor is configured to implement a method as in any of aspects 14-21.

Aspect 23 may be combined with aspect 22 and includes that the apparatus is a wireless communication device comprising at least one of a transceiver or an antenna coupled to the processor, wherein to obtain the set of bits, the processor is configured to obtain the set of bits via at least one of the transceiver or the antenna.

Aspect 24 is an apparatus for data processing including means for implementing a method as in any of aspects 14-21.

Aspect 25 is a computer-readable medium (e.g., a non-transitory computer-readable medium) storing computer executable code, the computer executable code, when executed by a processor, causes the processor to implement a method as in any of aspects 14-21.

Various aspects have been described herein. These and other aspects are within the scope of the following claims.

What is claimed is:

1. An apparatus for data processing, comprising:
a memory; and
a processor coupled to the memory and, based on information stored in the memory, the processor is configured to:
obtain a set of bits including a first subset of bits and a second subset of bits, wherein a bit width of the set of bits is greater than a configured bit width of compression hardware;
process the first subset of bits based on a parity corresponding to the second subset of bits; and
output, for a decoder of the compression hardware, the set of bits including the processed first subset of bits and the second subset of bits.

2. The apparatus of claim 1, wherein the parity corresponding to the second subset of bits indicates an odd number, and wherein to process the first subset of bits, the processor is configured to perform a bitwise NOT operation on the first subset of bits.

3. The apparatus of claim 1, wherein the parity corresponding to the second subset of bits indicates an even number, and wherein to process the first subset of bits, the processor is configured to refrain from adjusting the first subset of bits.

4. The apparatus of claim 1, wherein the first subset of bits corresponds to a least significant bit (LSB) component of the set of bits, and wherein the second subset of bits corresponds to a most significant bit (MSB) component of the set of bits.

5. The apparatus of claim 4, wherein to process the first subset of bits, the processor is configured to process the first subset of bits to remove a discontinuity associated with the LSB component.

6. The apparatus of claim 1, wherein the set of bits corresponds to a set of pixels in a frame.

7. The apparatus of claim 1, wherein to output the set of bits including the processed first subset of bits and the second subset of bits, the processor is configured to transmit, to the decoder of the compression hardware, the set of bits including the processed first subset of bits and the second subset of bits.

8. The apparatus of claim 1, wherein the processor is configured to:
compress the set of bits including the processed first subset of bits and the second subset of bits, wherein to output the set of bits including the processed first subset of bits and the second subset of bits, the processor is configured to output, to the decoder of the compression hardware, the compressed set of bits.

9. The apparatus of claim 1, wherein the bit width of the set of bits is 10 bits, 12 bits, 14 bits, or 16 bits.

10. The apparatus of claim 1, wherein the apparatus is a wireless communication device comprising at least one of a transceiver or an antenna coupled to the processor, wherein to output the set of bits, the processor is configured to output the set of bits via at least one of the transceiver or the antenna.

11. An apparatus for data processing, comprising:
a memory; and
a processor coupled to the memory and, based on information stored in the memory, the processor is configured to:
obtain, from an encoder of compression hardware, a set of bits including a first subset of bits and a second subset of bits, wherein a bit width of the set of bits is greater than a configured bit width of the compression hardware;
process the first subset of bits based on a parity corresponding to the second subset of bits; and
output the set of bits including the processed first subset of bits and the second subset of bits.

12. The apparatus of claim 11, wherein the parity corresponding to the second subset of bits indicates an odd number, and wherein to process the first subset of bits, the processor is configured to perform a bitwise NOT operation on the first subset of bits.

13. The apparatus of claim 11, wherein the parity corresponding to the second subset of bits indicates an even number, and wherein to process the first subset of bits, the processor is configured to refrain from adjusting the first subset of bits.

14. The apparatus of claim 11, wherein the first subset of bits corresponds to a least significant bit (LSB) component of the set of bits, and wherein the second subset of bits corresponds to a most significant bit (MSB) component of the set of bits.

15. The apparatus of claim 11, wherein the set of bits corresponds to a set of pixels in a frame.

16. The apparatus of claim 11, wherein to output the set of bits including the processed first subset of bits and the second subset of bits, the processor is configured to:
transmit the set of bits to a display; or
store the set of bits in at least one of the memory, a buffer, or a cache.

17. The apparatus of claim 11, wherein to obtain the set of bits including the processed first subset of bits and the second subset of bits, the processor is configured to receive a compressed set of bits including the processed first subset of bits and the second subset of bits, and wherein the processor is further configured to:
decompress the compressed set of bits including the processed first subset of bits and the second subset of bits, wherein to process the first subset of bits based on the parity corresponding to the second subset of bits, the processor is configured to process the decompressed first subsets of bits based on the parity corresponding to the decompressed second subset of bits.

18. The apparatus of claim 11, wherein the bit width of the set of bits is 10 bits, 12 bits, 14 bits, or 16 bits.

19. The apparatus of claim 11, wherein the apparatus is a wireless communication device comprising at least one of a transceiver or an antenna coupled to the processor, wherein to obtain the set of bits, the processor is configured to obtain the set of bits via at least one of the transceiver or the antenna.

20. A method of data processing, comprising:
obtaining a set of bits including a first subset of bits and a second subset of bits, wherein a bit width of the set of bits is greater than a configured bit width of compression hardware;
processing the first subset of bits based on a parity corresponding to the second subset of bits; and
outputting, for a decoder of the compression hardware, the set of bits including the processed first subset of bits and the second subset of bits.

21. The method of claim 20, wherein the parity corresponding to the second subset of bits indicates an odd number, and wherein processing the first subset of bits comprises performing a bitwise NOT operation on the first subset of bits.

22. The method of claim 20, wherein the parity corresponding to the second subset of bits indicates an even number, and wherein processing the first subset of bits comprises refraining from adjusting the first subset of bits.

23. The method of claim 20, wherein the first subset of bits corresponds to a least significant bit (LSB) component of the set of bits, and wherein the second subset of bits corresponds to a most significant bit (MSB) component of the set of bits.

24. The method of claim 23, wherein processing the first subset of bits removes a discontinuity associated with the LSB component.

25. The method of claim 20, wherein the set of bits corresponds to a set of pixels in a frame.

26. The method of claim 20, wherein outputting the set of bits including the processed first subset of bits and the second subset of bits comprises transmitting, to the decoder of the compression hardware, the set of bits including the processed first subset of bits and the second subset of bits.

27. The method of claim 20, further comprising:
compressing the set of bits including the processed first subset of bits and the second subset of bits, wherein outputting the set of bits including the processed first subset of bits and the second subset of bits comprises outputting, to the decoder of the compression hardware, the compressed set of bits.

28. The method of claim 20, wherein the bit width of the set of bits is 10 bits, 12 bits, 14 bits, or 16 bits.

29. A method of data processing, comprising:
obtaining, from an encoder of compression hardware, a set of bits including a first subset of bits and a second subset of bits, wherein a bit width of the set of bits is greater than a configured bit width of the compression hardware;
processing the first subset of bits based on a parity corresponding to the second subset of bits; and
outputting the set of bits including the processed first subset of bits and the second subset of bits.

30. The method of claim 29, wherein the parity corresponding to the second subset of bits indicates an odd number, and wherein processing the first subset of bits comprises performing a bitwise NOT operation on the first subset of bits.
